(19) United States
(12) Patent Application Publication
(10) Pub. No.: US 2026/0206277 A1
(43) Pub. Date: Jul. 16, 2026

(54) WRAP-AROUND SOURCE/DRAIN CONTACT STRUCTURES IN SEMICONDUCTOR DEVICES

(71) Applicant: Taiwan Semiconductor Manufacturing Company, Ltd., Hsinchu (TW)

(72) Inventors: Ching Hsiang CHANG, New Taipei City (TW); Chun-Chun LU, Hsinchu (TW); Chi-Ruei YEH, New Taipei City (TW); Tsung-Yu CHIANG, New Taipei City (TW)

(73) Assignee: Taiwan Semiconductor Manufacturing Company, Ltd., Hsinchu (TW)

(21) Appl. No.: 19/018,924

(22) Filed: Jan. 13, 2025

(51) Int. Cl. H10D 64/23; H10D 30/00; H10D 30/01; H10D 64/01

(52) U.S. Cl. CPC H10D 64/251; H10D 30/019; H10D 30/501; H10D 64/01

(57) ABSTRACT

This disclosure is directed to a structure of a semiconductor device and a method of forming the structure. The structure includes a fin structure on a substrate. The fin structure includes channel layers. The structure further includes a gate structure surrounding each of the channel layers, a source/drain (S/D) region adjacent to the fin structure and in contact with the channel layers, an insulating layer adjacent to the S/D region, and a dielectric layer on the S/D region and the insulating layer. The structure further includes an S/D contact structure through the dielectric layer and in contact with the S/D region and the insulating layer. A bottom surface of the S/D contact structure is below a top surface of a bottommost channel layer of the channel layers.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs). Such scaling down has increased the complexity of semiconductor manufacturing processes.

### BRIEF DESCRIPTION OF THE DRAWINGS

Aspects of the present disclosure are best understood from the following detailed description when read with the accompanying figures. It is noted that, in accordance with the common practice in the industry, various features are not drawn to scale. In fact, the dimensions of the various features may be arbitrarily increased or reduced for clarity of illustration and discussion.

FIG. 1 is an isometric view of a semiconductor device including semiconductor transistors, in accordance with some embodiments.

FIGS. 2A, 2B, and 2C are cross-sectional views of a semiconductor device including semiconductor transistors, in accordance with some embodiments.

FIGS. 3A and 3B are cross-sectional views of semiconductor devices including semiconductor transistors, in accordance with some embodiments.

FIGS. 4A and 4B are flowcharts of methods for the formation of semiconductor devices including semiconductor transistors, in accordance with some embodiments.

FIGS. 5 and 6 are isometric views of intermediate structures during the fabrication of a gate contact structure of a semiconductor transistor, in accordance with some embodiments.

FIGS. 7, 8, 9, 10, 11, 12, 13, 14, 15, 16, 17A, 18, 19, 20, 21, 22, 23, and 24 are cross-sectional views of intermediate structures during the fabrication of a semiconductor transistor, in accordance with some embodiments.

FIG. 17B is a top view of an intermediate structure during the fabrication of a semiconductor transistor, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “about” and “substantially” can refer to a percentage of the values as interpreted by those skilled in relevant art(s) in light of the teachings herein.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

By way of example and not limitation, nanostructure transistors, like GAA nano-sheet (NS) or nano-wire (NW) FETs (collectively referred to as “GAAFETs”) with nano-sheet (NS) or nano-wire (NW) channel regions, can be formed as follows. A fin-like structure with alternating silicon-germanium (SiGe) and silicon (Si) NS or NW layers is formed on a substrate (e.g., on semiconductor substrate). A sacrificial gate structure is then formed on a middle portion of the fin-like structure to cover top and sidewall surfaces of the fin-like structure so that edge portions of the fin-like structure are not covered by the sacrificial gate structure. The edge portions of the fin-like structure not covered by the sacrificial gate structure are removed. Subsequently, edge portions of the SiGe NS or NW layers are recessed with respect to edge portions of the Si NS or NW layers, and an inner spacer structure is formed by depositing a dielectric material to fill the space formed by the etched portions of the SiGe NS or NW layers. Source/drain (S/D) epitaxial structures are then formed to abut (or to be in contact with) edge portions of the fin-like structures so that the S/D epitaxial structures are in contact with the Si NS or NW layers and isolated (or separated) from the SiGe NS or NW layers by the inner spacer structures. Source/drain may refer to a source or a drain, individually or collectively dependent upon the context. In a subsequent operation, the sacrificial gate structure is removed to expose the top and sidewall surfaces of the fin-like structure. The SiGe NS or NW layers are selectively removed from the fin-like structure. During the selective removal process, the Si NS or NW layers and the inner spacer structures are not removed. Subsequently, a metal gate structure is formed to surround the Si NS or NW layers. Similar to the SiGe NS or NW layers prior to their selective removal, the metal gate structure is isolated (or separated) from the S/D epitaxial structures through the inner spacer structures. An S/D contact structure can be formed in contact with the S/D epitaxial structure, and a gate contact structure can be formed in contact with the metal gate structure. The S/D contact structure and the gate contact structure can be in contact with an interconnect structure such that the GAAFET can electrically couple with other nanostructure transistors.

The structure of the GAAFETs may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

As semiconductor devices continue scaling down, in the exemplary GAAFET formed by the process described above, critical dimensions of the GAAFET, such as lengths/widths of the Si NS or NW layers as channels and the S/D epitaxial structures are getting smaller. Accordingly, a contact area between the S/D contact structure and the S/D epitaxial structure is reduced, resulting in greater contact resistance, which would impact the operation speed of the GAAFET while generating more heat. In addition, current paths from edge portions of the Si NS or NW layers through the S/D epitaxial structure to the S/D contact structure are different. For example, the topmost Si NS or NW layer is the closest to the S/D contact structure and has the shortest current path through a short distance in the S/D epitaxial structure. By contrast, the bottommost Si NS or NW layer is the farthest to the S/D contact structure and has the longest current path through a large distance in the S/D epitaxial structure. Such a variation of the lengths of the current paths can give rise to uneven electrical characteristics among the Si NS or NW layers as channels of the GAAFET, and can become more drastic when the critical dimensions of the S/D epitaxial structure gets smaller. For example, the current paths through different Si NS or NW layers can experience different resistances, hence different resistance-capacitance constants and response times, which would compromise the performance of the GAAFET.

The embodiments described herein are directed to overcome the challenges mentioned above. In some embodiments, a structure of a semiconductor device can include an insulating layer adjacent to an S/D epitaxial structure of a GAAFET with multiple channel layers. The structure can further include an S/D contact structure protruding into the insulating layer and the S/D structure. The S/D contact structure can have a shape that wraps around a majority of a side surface of the S/D epitaxial structure, and can vertically extend between the insulating layer and the S/D epitaxial structure to or below a horizontal level of a bottom most channel layer of the GAAFET. With the S/D contact structure wrapping around the S/D epitaxial structure in such a geometry, a contact area between the S/D contact structure and the S/D epitaxial structure can be increased, reducing the contact resistance between the two structures. In addition, by wrapping around the side surface of the S/D epitaxial structure, the S/D contact structure can extend closer to the bottommost channel, mitigating the aforementioned issue caused by the variation of the lengths of the current paths and improving the performance of the GAAFET. In some embodiments, a method of forming the structure can include forming the S/D epitaxial structure adjacent to the channel layers and forming the insulating layer adjacent to the S/D epitaxial structure. The method can further include forming a dielectric layer and a patterned mask on the insulating layer and the S/D epitaxial structure. The patterned mask can have a window overlapping with an interface between the insulating layer and the S/D epitaxial structure. The method can further include forming an opening according to the patterned mask through the dielectric layer and protruding into the insulating layer and the S/D epitaxial structure. The opening can be formed by etching the insulating layer and the S/D epitaxial structure with different selectivity such that the opening extends deeper in the insulating layer than in the S/D epitaxial structure. The method can further include depositing a conductive material in the opening to form the S/D contact structure wrapping around the S/D epitaxial structure.

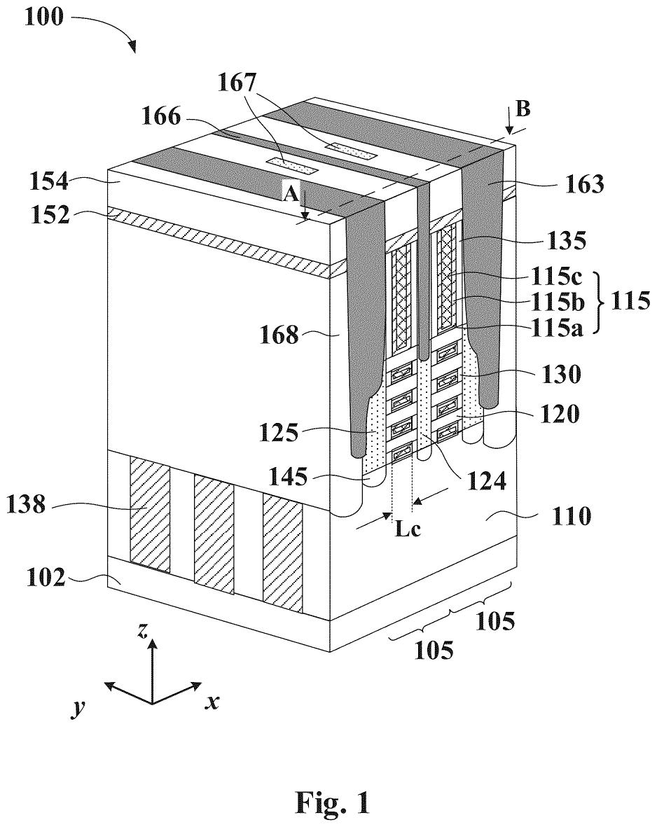

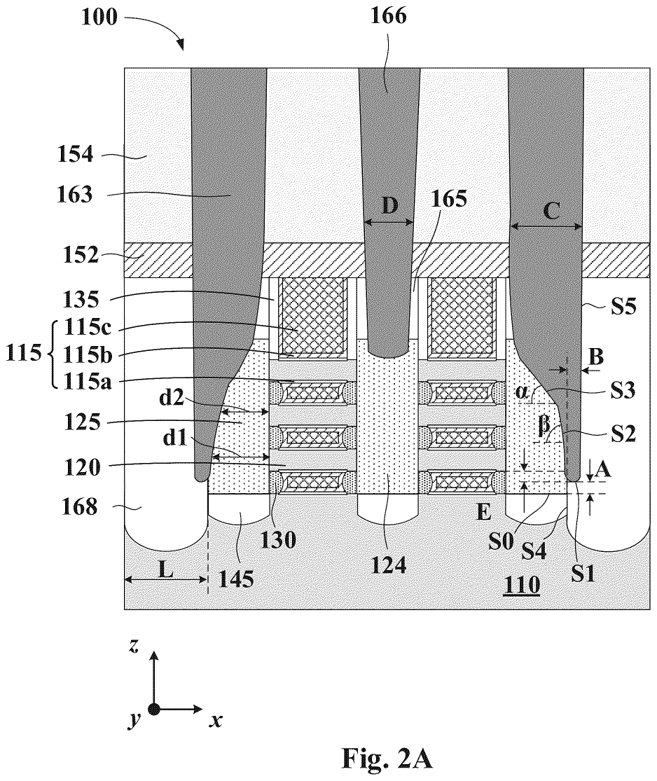

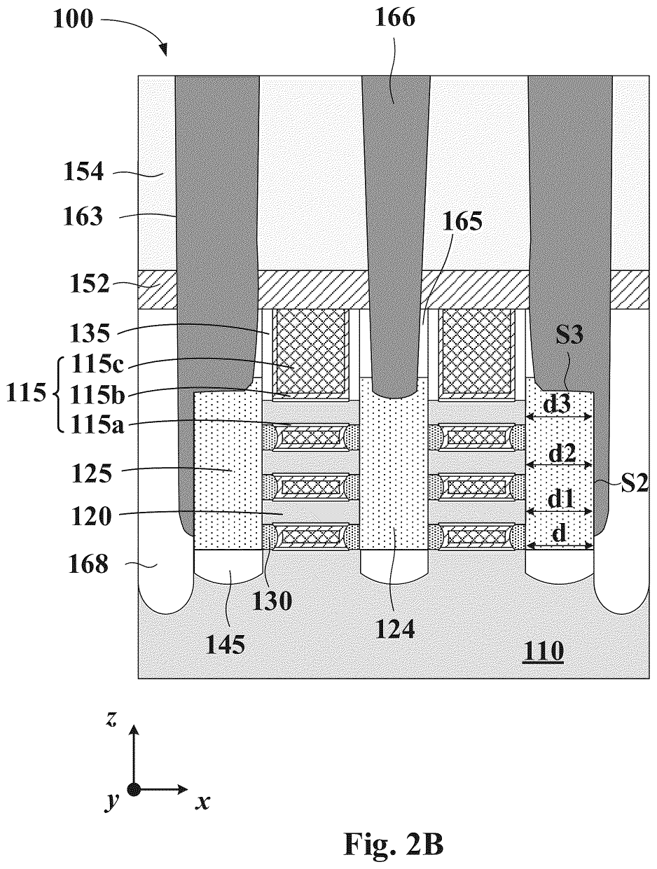

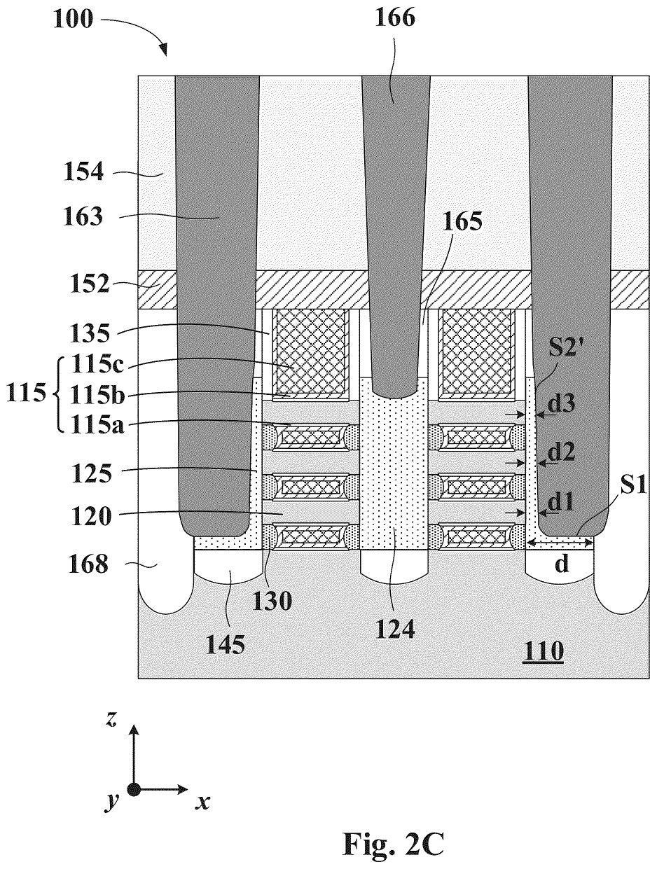

A semiconductor device 100 having multiple transistors 105 formed over a substrate 102 is described with reference to FIGS. 1 and 2A, according to some embodiments. Semiconductor device 100 can be included in a microprocessor, memory cell, or other integrated circuit (IC). FIG. 1 illustrates an isometric view of semiconductor device 100. FIG. 2A illustrates a cross-sectional (e.g., along the x-z plane) view of semiconductor device 100 along line A-B of FIG. 1.

Referring to FIG. 1, substrate 102 can be a semiconductor material, such as silicon. In some embodiments, substrate 102 can include a crystalline silicon substrate (e.g., wafer). In some embodiments, substrate 102 can include (i) an elementary semiconductor, such as silicon (Si) or germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, substrate 102 can be doped depending on design requirements (e.g., p-type substrate or n-type substrate). In some embodiments, substrate 102 can be doped with p-type dopants (e.g., boron (B), indium (In), aluminum (Al), or gallium (Ga)) or n-type dopants (e.g., phosphorus (P), arsenic (As), or antimony (Sb)). In some embodiments, a crystal orientation of substrate 102 can be (100), (110), or (111).

Although FIGS. 1 and 2A show fin structure 110 accommodating two transistors 105, any number of transistors 105 can be disposed along fin structure 110. In some embodiments, transistors 105 can include multiple fin structures 110 extending along a first horizontal direction (e.g., in the x-direction). In some embodiments, a crystal orientation of fin structures 110 can be the same as the crystal orientation of substrate 102.

Referring to FIGS. 1 and 2, each transistor 105 can include one or more nano-sheet (NS) layers 120 disposed over fin structure 110. Each NS layer 120 can function as transistor 105's channel. Each transistor 105 can also include a gate structure 115 wrapping each NS layer 120. For example, a top surface, side surfaces, and a bottom surface of each NS layer 120 can be surrounded and in physical contact with gate structure 115. Fin structure 110 and NS layer 120 can be made of materials similar to (e.g., lattice mismatch within about 5%) substrate 102. In some embodiments, a crystal orientation of NS layer 120 can be the same as the crystal orientation of fin structures 110. In some embodiments, each of fin structure 110 and NS layer 120 can be made of Si or SiGe. Each of fin structure 110 and NS layer 120 can be un-doped, doped with p-type dopants, doped with n-type dopants, or doped with intrinsic dopants. In some embodiments, fin structure 110 and NS layers 120 can be doped together with p-type dopants or with n-type dopants. Although FIG. 1 shows that each transistor 105 includes four NS layers 120, and FIG. 2A shows that each transistor 105 includes three NS layers 120. Any number of NS layers 120 can be included in each transistor 105. For example, each transistor 105 can include one, two, five, or six NS layers 120.

Referring to FIGS. 1 and 2A, gate structures 115 can be a multilayered structure that wraps around each NS layer 120 to modulate a resistance of transistor 105. In some embodiments, gate structure 115 can traverse through the multiple fin structures 110 along a second horizontal direction (e.g., in the y-direction) different from the first horizontal direction. Gate structure 115 can have a length Lc representing transistor 105's channel length. Length Lc can have any suitable horizontal (e.g., in the x-direction) dimension, such as from about 3 nm to about 200 nm. In some embodiments, a height of gate structures 115 along a vertical direction (e.g., in the z-direction) above fin structure 110 can be between about 12 nm and about 14 nm. In some embodiments, the height of gate structures 115 above fin structure 110 can be greater than about 14 nm. By way of example and not limitation, each gate structure 115 can include a dielectric stack formed by an interfacial dielectric layer 115a and a gate dielectric layer 115b. Further, each gate structure 115 includes a gate electrode 115c with capping layers, one or more work function metallic layers, and a metal fill not individually shown in FIGS. 1 and 2A for simplicity. Gate dielectric layer 115 b can include any suitable dielectric material with any suitable thickness that can provide channel modulation for transistor 105. In some embodiments, gate dielectric layer 115b can be made of silicon oxide or a high-k dielectric material (e.g., hafnium oxide or aluminum oxide). In some embodiments, gate dielectric layer 115b can have a thickness ranging from about 1 nm to about 5 nm. Based on the disclosure herein, other materials and thicknesses for gate dielectric layer 115b are within the scope and spirit of this disclosure. Gate electrode 115c can function as a gate terminal for transistor 105. Gate electrode 115c can include any suitable conductive material that provides a suitable work function to modulate the resistance of transistor 105. In some embodiments, gate electrode 115c can be made of titanium nitride, tantalum nitride, tungsten nitride, titanium, aluminum, copper, tungsten, tantalum, copper, or nickel. Based on the disclosure herein, other materials for gate electrode 115c are within the scope and spirit of this disclosure.

Referring to FIGS. 1 and 2A, each transistor 105 can further include S/D epitaxial structures 124 and 125 disposed over opposite sides (e.g., along the x-direction) of each NS layer 120 to function as transistor 105's source and drain terminals. S/D epitaxial structures 124 and 125 can be disposed on fin structures 110. In some embodiments, isolation layers 145 can be disposed in fin structure 110, and S/D epitaxial structures 124 and 125 can be disposed on isolation layers 145. Isolation layers 145 can include a dielectric material, such as silicon oxide or silicon nitride, to electrically isolate S/D epitaxial structures 124/125 and fin structures 110. S/D epitaxial structures 124 and 125 can be made of an epitaxially-grown semiconductor material similar to (e.g., lattice mismatch within about 5%) NS layer 120. In some embodiments, S/D epitaxial structures 124 and 125 can be made of Si, Ge, SiGe, InGaAs, or GaAs. S/D epitaxial structures 124 and 125 can be doped with p-type dopants, n-type dopants, or intrinsic dopants. In some embodiments, S/D epitaxial structures 124 and 125 can have a different doping type from NS layer 120. In some embodiments, the n-type dopants in S/D epitaxial structures 124 and 125 can include P, As, Sb, or a combination thereof. In some embodiments, a crystal orientation of S/D epitaxial structures 124 and 125 can be the same as the crystal orientation of NS layer 120.

In some embodiments, S/D epitaxial structures 124 and 125 can be different. In particular, S/D epitaxial structure 124 can be a common source/drain of two adjacent transistors 105 and can be disposed between the two sets of NS layers 120 of the two adjacent transistors 105. S/D epitaxial structure 125, on the other hand, can be a source/drain of a single transistor 105 and can be disposed between NS layers 120 of the single transistor 105 and an adjacent insulating layer 168. In some embodiments, insulating layer 168 can be disposed on fin structure 110. In some embodiments, insulating layer 168 can be in contact with S/D epitaxial structure 124 and isolation layer 145. In some embodiments, a length L of insulating layer 168 can substantially the same as length Lc of gate structure 115. In some embodiments, insulating layer 168 can protrude into fin structure 110 such that a bottom surface of insulating layer 168 is below bottom surfaces of S/D epitaxial structures 124 and 125 and/or bottom surfaces of isolation layers 145. In some embodiments, the bottom surface of insulating layer 168 can be curved. For example, the bottom surface of insulating layer 168 can be convex. In some embodiments, the bottom surface of insulating layer 168 can be flat. In some embodiments, insulating layer 168 can include a dielectric material, such as an oxide material (e.g., silicon oxide). In some embodiments, insulating layer 168 can include low-k silicon nitride (e.g., silicon nitride having a dielectric constant less than about 4). In some embodiments, insulating layer 168 can include intrinsic silicon.

Referring to FIGS. 1 and 2A, semiconductor device 100 can include inner spacer structures 130 abutting (or in contact with) side surfaces of gate structures 115. Inner spacer structures 130 can separate gate structures 115 from S/D epitaxial structures 124 and 125. For example, inner spacer structures 130 can be formed at gate structures 115's opposite sides along transistors 105's channel direction (e.g., along the x-direction) to separate gate structures 115 from S/D epitaxial structures 124 and 125. In some embodiments, inner spacer structures 130 can be formed between two vertically (e.g., in the z-direction) adjacent NS layers 120. In some embodiments, inner spacer structures 130 can be formed between fin structures 110 and a bottommost NS layer 120. In some embodiments, inner spacer structures 130 can include a silicon-based dielectric, such as silicon nitride (SiN), silicon oxy-carbon-nitride (SiOCN), silicon carbon-nitride (SiCN), and silicon oxy-nitride (SiON). In some embodiments, inner spacer structures 130 can include a low-k material, such as a porous material and a carbon-rich silicon oxide based dielectrics.

Referring to FIGS. 1 and 2A, semiconductor device 100 can further include gate spacers 135 formed between gate structure 115 and S/D epitaxial structure 124/125. Gate spacers 135 can provide structural support during the formation of gate structures 115. Gate spacers 135 can be made of any suitable dielectric material. In some embodiments, gate spacers 135 can be made of silicon oxide, silicon nitride, or a low-k material with a dielectric constant less than about 3.9. In some embodiments, gate spacers 135 can have any suitable thickness, such as from about 5 nm to about 15 nm. Based on the disclosure herein, other materials and thicknesses for gate spacers 135 are within the scope and spirit of this disclosure.

Referring to FIG. 1, semiconductor device 100 can further include shallow trench isolation (STI) regions 138 configured to provide electrical isolation between fin structures 110. STI regions 138 can also provide electrical isolation between transistor 105 and neighboring active and passive elements integrated with or deposited on substrate 102. STI regions 138 can include one or more layers of dielectric material, such as a nitride layer, an oxide layer disposed on the nitride layer, and an insulating layer disposed on the nitride layer. In some embodiments, the insulating layer can include silicon oxide, silicon nitride, silicon oxynitride, fluorine-doped silicate glass (FSG), a low-k dielectric material, and/or other suitable insulating materials. Based on the disclosure herein, other dielectric materials for STI regions 138 are within the scope and spirit of this disclosure.

Referring to FIGS. 1 and 2, semiconductor device 100 can further include interlayer dielectric (ILD) layers 165 disposed between fin structures 110 and on S/D epitaxial structures 124 and 125 to provide electrical isolation to structural elements it surrounds or covers, such as gate structures 115 and S/D epitaxial structures 124 and 125. In some embodiments, gate spacers 135 can be formed between gate structures 115 and ILD layers 165. ILD layers 165 can include any suitable dielectric material to provide electrical insulation, such as silicon oxide, silicon dioxide, silicon oxycarbide, silicon oxynitride, silicon oxy-carbon nitride, and silicon carbonitride. ILD layers 165 can have any suitable thickness, such as from about 50 nm to about 200 nm, to provide electrical insulation. Based on the disclosure herein, other insulating materials and thicknesses for ILD layers 165 are within the scope and spirit of this disclosure.

Referring to FIGS. 1 and 2A, semiconductor device 100 can further include an etch stop layer (ESL) 152 on transistors 105 and a dielectric layer 154 on ESL 152. In some embodiments, ESL 152 and dielectric layer 154 can include silicon oxide and/or silicon nitride. For example, ESL 152 can be a layer of silicon nitride and dielectric layer 154 can be a layer of silicon oxide, or vice versa.

Referring to FIG. 1, semiconductor device 100 can further include one or more gate contact vias 167 in contact with gate electrode 115c. Gate contact via 167 can be disposed on gate structures 115 and through ESL 152 and dielectric layer 154.

Referring to FIGS. 1 and 2A, semiconductor device 100 can further include an S/D contact 166 in contact with S/D epitaxial structures 124. S/D contacts 166 can extend through ESL 152, dielectric layer 154, and ILD layer 165. In some embodiments, a height of S/D contact 166 can be between about 10 nm and about 50 nm. In some embodiments, an interface between S/D contact 166 and S/D epitaxial structures 124 can be substantially flat. In some embodiments, the interface between S/D contact 166 and S/D epitaxial structures 124 can be curved. In some embodiments, a horizontal cross section of S/D contact 166 can have a rectangular shape or a cylindrical shape. In some embodiments, S/D contact 166 can have a tapered shape with a width of a top surface greater than a width of a bottom surface. In some embodiments, S/D contact 166 can have a uniform width from its top surface to its bottom surface. In some embodiments, a width D of S/D contact 166 can be between about 2 nm and about 50 nm. S/D contacts 166 can include any suitable conductive material that provides low contact resistance with S/D epitaxial structures 124. In some embodiments, S/D contacts 166 can be made of polysilicon, titanium nitride, tantalum nitride, tungsten nitride, titanium, aluminum, copper, tungsten, tantalum, nickel, or a combination thereof. Based on the disclosure herein, other materials for S/D contacts 166 are within the scope and spirit of this disclosure.

Referring to FIGS. 1 and 2A, semiconductor device 100 can further include an S/D contact 163 in contact with S/D epitaxial structures 125 and insulating layer 168. S/D contacts 163 can extend through ESL 152, dielectric layer 154 and ILD layer 165. In some embodiments, S/D contact 163 can wrap over a majority of or an entirety of a side surface of S/D epitaxial structures 125. For example, S/D contact 163 can extend from a top surface of S/D epitaxial structures 125 to close to a bottom surface S0 of S/D epitaxial structures 125. With such a “wrap-around” geometry, S/D contact 163 can form a large contact area with S/D epitaxial structures 125 and reduce their contact resistance. S/D contact 163 can also be referred to as wrap-around S/D contact 163. Different from S/D contact 163, S/D contact 166 is in contact with S/D epitaxial structures 124 in a region close to a top surface of S/D epitaxial structures 124. S/D contact 166 can be referred to as regular S/D contact 166.

As shown in FIG. 2A, a bottom surface S1 of S/D contact 163 can be an interface S1 between S/D contact 163 and insulating layer 168. In some embodiments, S/D contact 163 can extend vertically approaching or over bottom surface S0 of S/D epitaxial structures 125. For example, interface S1 can be above bottom surface S0 by a vertical distance A between about 0 nm and about 50 nm. In some embodiments, interface S1 can be below bottom surface S0 by vertical distance A between about 0 nm and about 50 nm. For example, vertical distance A can be between about 0 nm and about 20 nm. In some embodiments, interface S1 can be below a top surface of the bottommost NS layer 120. In some embodiments, interface S1 can be below a bottom surface of the bottommost NS layer 120. For example, interface S1 can be below the bottom surface of the bottommost NS layer 120 by a vertical distance E between about 0 nm and about 20 nm. The extension of S/D contact 163 over a horizontal level of the bottommost NS layer 120 can ensure that a current path from the bottommost NS layer 120 to S/D contact 163 can have a similar length compared with those through other NS layers 120, such that the electrical characteristics of different NS layers 120 can be substantially uniform. For example, a first horizontal distance d1 between S/D contact 163 and the bottommost NS layer 120 can be similar to a second horizontal distance d2 between S/D contact 163 and a second bottommost NS layer 120 above the bottommost NS layer 120. In some embodiments, a ratio of first horizontal distance d1 to second horizontal distance d2 can be between about 1 and about 1.2. In some embodiments, interface S1 can be curved. In some embodiments, interface S1 can be flat.

In some embodiments, an interface between S/D contact 163 and S/D epitaxial structures 125 can include a lower interface S2 and an upper interface S3 above lower interface S2. In some embodiments, lower interface S2 and upper interface S3 can be slated with respect to a horizontal direction (e.g., the x-axis). In some embodiments, upper interface S3 can be more slanted or inclined than lower interface S2. For example, an angle β between lower interface S2 and the x-axis can be greater than an angle α between upper interface S3 and the x-axis. In some embodiments, angle α can be between about 45° and about 70°, and angle β can be between about 65° and about 90°.

In some embodiments, S/D epitaxial structure 125 and insulating layer 168 can be in contact with each other at an interface S4. In some embodiments, interface S4 can be vertical with respect to a horizontal direction (e.g., the x-axis). In some embodiments, S/D contact 163 can horizontally protrude into insulating layer 168 with respect to interface S4 and in contact with insulating layer 168 at interface S5. In some embodiments, interface S5 can be vertical with respect to a horizontal direction (e.g., the x-axis). In some embodiments, a horizontal distance B between interfaces S4 and S5 can be between about 0 nm and about 50 nm. For example, horizontal distance B can be between about 0 nm and about 20 nm. In some embodiments, a width C of S/D contact 163 can be between about 5 nm and about 100 nm. In some embodiments, a ratio of width C to horizontal distance B can be between about 2 and about 5. In some embodiments, a ratio of width C of S/D contact 163 to width D of S/D contact 166 can be between about 1 and about 5. For example, the ratio of width C to width D can be between about 1.5 and about 3.

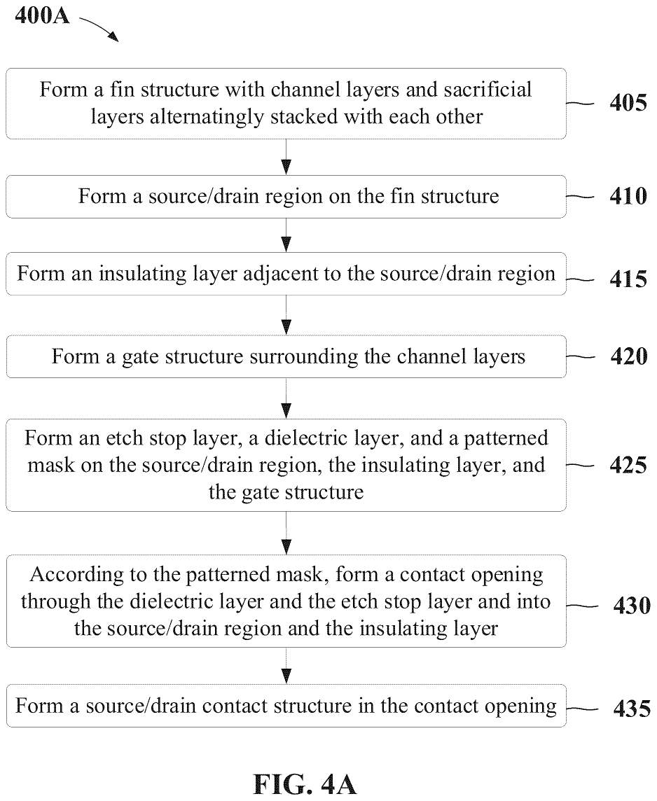

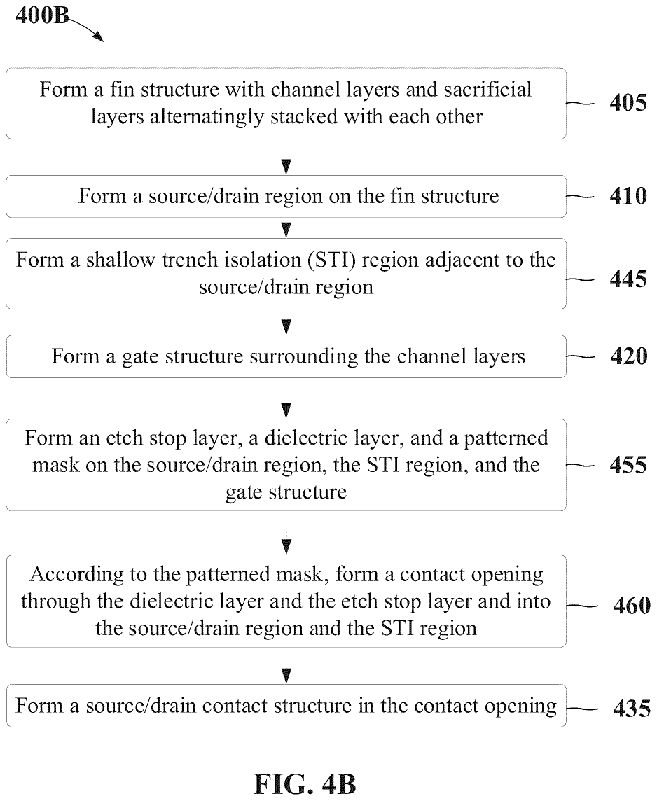

S/D contact 163 with the above geometrical features can be formed by etching S/D epitaxial structures 125 and insulating layer 168 with different etching rates to form a contact opening, as further discussed below in methods 400A and 400B with reference to FIGS. 4A and 4B, respectively. In particular, using an etchant that etches insulating layer 168 at a higher etching rate than S/D epitaxial structures 125, the contact opening can be formed faster and deeper into insulating layer 168 than into S/D epitaxial structures 125. Therefore, in addition to etching S/D epitaxial structures 125 vertically from the top, the etchant can remove S/D epitaxial structures 125 horizontally from the side of insulating layer 168, forming slopes of the contact opening on S/D epitaxial structures 125. A subsequent deposition of a conductive material into the contact opening can form S/D contact 163 with bottom surface S1 extending into insulating layer 168 and with slated lower interface S2 and upper interface S3 with S/D epitaxial structures 125. S/D contacts 163 can include any suitable conductive material that provides low contact resistance with S/D epitaxial structures 125. In some embodiments, S/D contacts 163 can be made of polysilicon, titanium nitride, tantalum nitride, tungsten nitride, titanium, aluminum, copper, tungsten, tantalum, nickel, or a combination thereof. Based on the disclosure herein, other materials for S/D contacts 163 are within the scope and spirit of this disclosure. In some embodiments, S/D contacts 163 can include a same conductive material as S/D contacts 166.

In some embodiments, an etching selectivity of the etchant, as defined by a ratio of a first etching rate on insulating layer 168 to a second etching rate on S/D epitaxial structures 125, can be between about 1 and about 10. By choosing the etchant with different etching selectivities with respect to etching S/D epitaxial structures 125 and insulating layer 168, the geometrical profile of S/D contacts 163 can be controlled, as shown in FIGS. 2B and 2C. FIGS. 2B and 2C illustrate cross-sectional (e.g., along the x-z plane) views of semiconductor device 100 along line A-B of FIG. 1. The discussion of elements in FIGS. 1 and 2A with the same annotations applies to FIGS. 2B and 2C, unless mentioned otherwise.

Referring to FIG. 2B, S/D contacts 163 can have a shape of a cleaver (e.g., a cleaver having a rectangular blade bound by a straight handle) and can be made by using an etchant with a higher etching selectivity than that used to form S/D contacts 163 in FIG. 2A. In some embodiments, as shown in FIG. 2B, during the etching process to form the contact opening, insulating layer 168 can be etched faster than S/D epitaxial structures 125, such that lower interface S2 can be substantially perpendicular to a horizontal axis (e.g., the x-axis). For example, an angle between lower interface S2 and the x-axis can be between about 85° and about 90°. In some embodiments, lower interface S2 can be substantially coplanar with interface S4 between S/D epitaxial structures 125 and insulating layer 168. In addition, upper interface S3 can be substantially parallel to a horizontal axis (e.g., the x-axis). For example, an angle between upper interface S3 and the x-axis can be between about 0° and about 10°. In some embodiments, upper interface S3 can be horizontally above an upper surface of a topmost NS layer 120. In some embodiments, horizontal lengths d1-d3 between NS layers 120 and S/D contacts 163 can be substantially the same. For example, a variation of lengths d1-d3 can be less than 10%. In some embodiments, a ratio of lengths d1-d3 to width d of S/D epitaxial structures 125 can be between about 0.8 and about 1.

Referring to FIG. 2C, S/D contacts 163 can have a rectangular shape and can be made by using an etchant with a lower etching selectivity than those used to form S/D contacts 163 in FIGS. 2A and 2B. In some embodiments, as shown in FIG. 2C, during the etching process to form the contact opening, insulating layer 168 can be etched at a similar rate as S/D epitaxial structures 125. As a result, an interface S2′ between S/D contacts 163 and S/D epitaxial structures 125 can be substantially perpendicular to a horizontal axis (e.g., the x-axis). For example, an angle between interface S2′ and the x-axis can be between about 85° and about 90°. In some embodiments, horizontal lengths d1-d3 between NS layers 120 and S/D contacts 163 can be substantially the same. For example, a variation of lengths d1-d3 can be less than 10%. In some embodiments, a ratio of lengths d1-d3 to width d of S/D epitaxial structures 125 can be between about 0.1 and about 0.5. In some embodiments, bottom surface S1 of S/D contact 163 can be interface S1 between S/D contact 163 and S/D epitaxial structures 125. In some embodiments, bottom surface S1 can be flat.

As shown in FIGS. 1 and 2A-2C, semiconductor device 100 can include two GAAFETs adjacent to each other in series with common S/D epitaxial structures 124 disposed in between first and second sets of NS layers 120. Semiconductor device 100 can also include a first S/D epitaxial structure 125 on one side of the first set of NS layers 120 and a second S/D epitaxial structure 125 on an opposite side of the second set of NS layers 120. Semiconductor device 100 can further include first and second insulating layers adjacent to the first and second S/D epitaxial structures 125, respectively. Semiconductor device 100 can further include first and second S/D contacts 163 in contact with the first and second S/D epitaxial structures 125, respectively. In some embodiments, first and second S/D contacts 163 can be formed together and can be symmetrical with respect to a plane between them. For example, first and second S/D contacts 163 can be symmetrical with respect to a perpendicular plane bisecting common S/D epitaxial structures 124. In some embodiments, first and second S/D contacts 163 can be formed differently (with different etchants forming the corresponding contact openings), such that the first and second S/D contacts 163 can be asymmetrical. For example, first S/D contacts 163 can be that in FIG. 2A and second S/D contacts 163 can be that in FIG. 2B or 2C. In some embodiments, first S/D contacts 163 can be that in FIG. 2B and second S/D contacts 163 can be that in FIG. 2C.

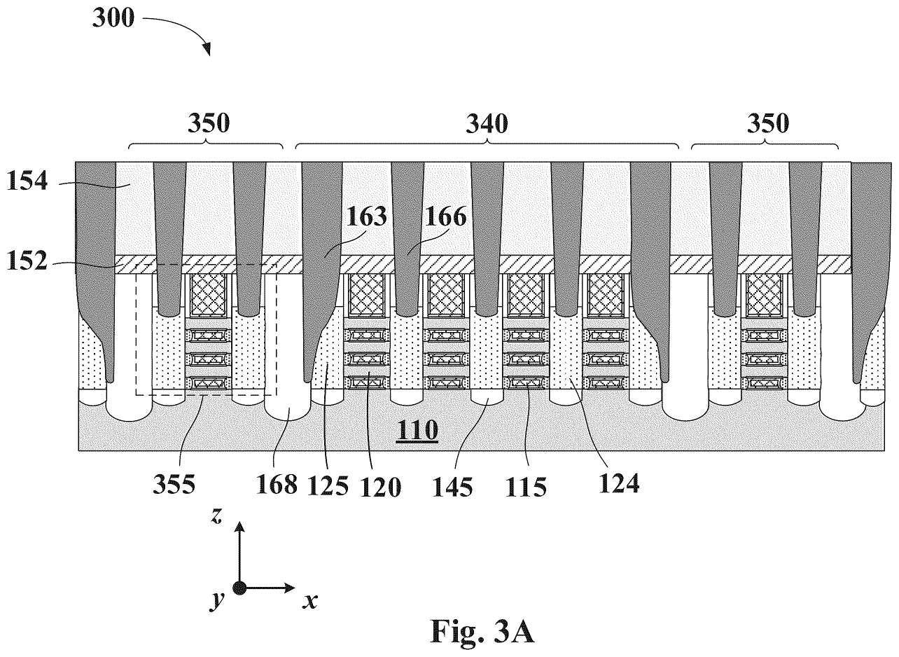

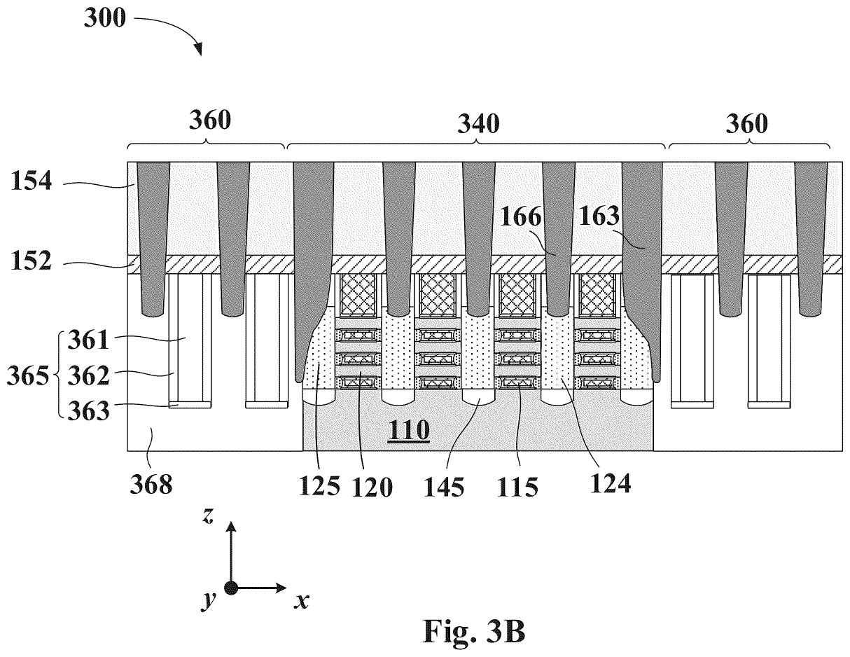

Although FIGS. 1 and 2A-2C show that semiconductor device 100 can include two GAAFETs in series between two wrap-around S/D contacts 163, it should be understood that any number of GAAFETs in series can be disposed between two wrap-around S/D contacts 163. For example, a semiconductor device can include only one GAAFET 105 between two insulating layers 168 and with first and second S/D epitaxial structures 125 respectively wrap-around by first and second S/D contacts 163, which can be symmetrical with respect to a perpendicular plain bisecting gate structure 115. In some embodiments, a semiconductor device can include more than two GAAFETs in series between two wrap-around S/D contacts 163, as shown in FIGS. 3A and 3B. FIGS. 3A and 3B illustrate cross-sectional (e.g., along the x-z plane) views of a semiconductor device 300. The discussion of elements in FIGS. 1 and 2A-2C with the same annotations applies to FIGS. 3A and 3B, unless mentioned otherwise.

Referring to FIG. 3A, semiconductor device 300 can include an active region 340 and two dummy regions 350 adjacent to active region 340. Insulating layers 168 can be disposed at the boundary between active region 340 and dummy regions 350. As discussed below in method 400A with reference to FIG. 4A, insulating layers 168 can be formed by replacing certain channel layers on fin structure 110 with dielectric materials. As shown in FIG. 3A, active region 340 between insulating layers 168 can include four GAAFETs in series connected by three common S/D epitaxial structures 124 and having two S/D epitaxial structures 125 adjacent to insulating layers 168. Accordingly, active region 340 can include three regular S/D contacts 166 in contact with the three common S/D epitaxial structures 124 and two wrap-around S/D contacts 163 in contact with the two S/D epitaxial structures 125. The two wrap-around S/D contacts 163 can be any of S/D contacts 163 as discussed above with reference to FIGS. 1 and 2A-2C. In some embodiments, each dummy region 350 can include one or more dummy transistors 355 with their S/D epitaxial structures 124 in contact with regular S/D contacts 166. Dummy transistors 355 may not perform any function for the operation of semiconductor device 300 and may have their regular S/D contacts 166 or gate contact structures electrically coupled to a ground potential. In some embodiments, dummy transistors 355 can have complete structures as GAAFETs in active region 340. In some embodiments, dummy transistors 355 can have partially completed structures. For example, dummy transistors 355 can have dummy gate structures without being replaced by gate structures 115 as GAAFETs in active region 340. In some embodiments, the presence of dummy transistors 355 in dummy regions 350 can maintain a uniformity of mechanical properties of semiconductor device 300 during a manufacturing process to avoid dishing issues due to a loading effect.

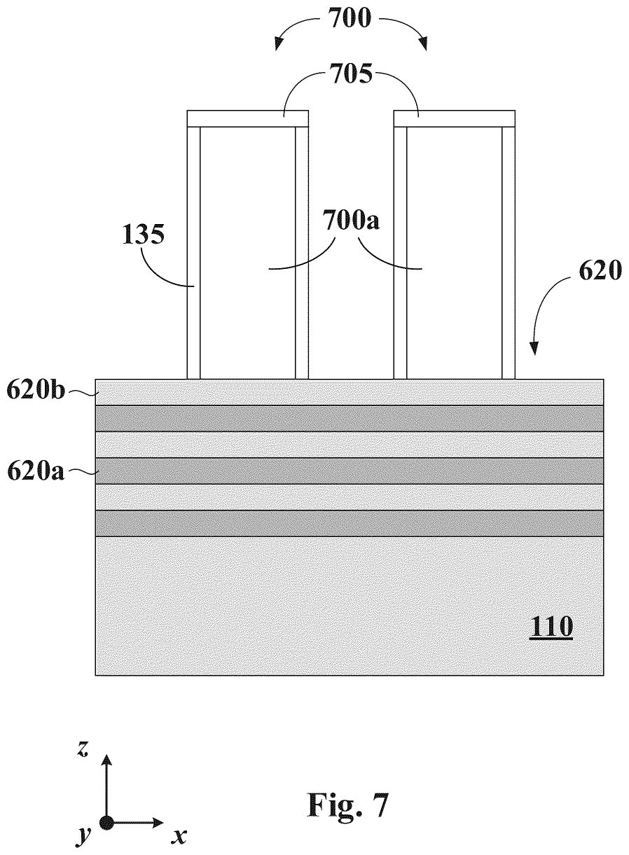

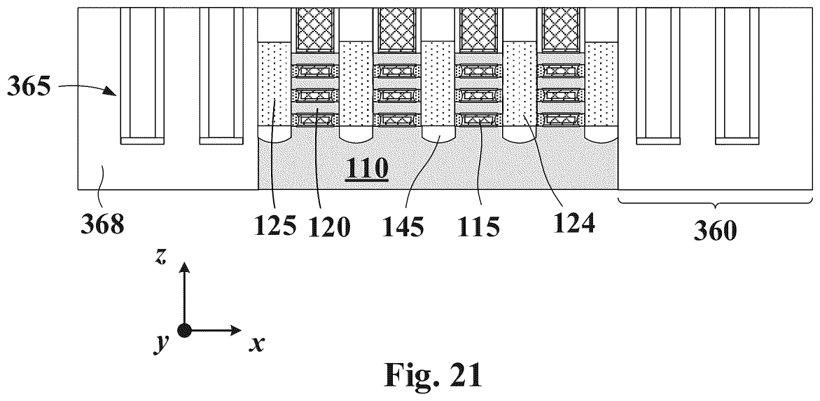

Referring to FIG. 3B, semiconductor device 300 can include active region 340 and two STI regions 360 adjacent to active region 340. The discussion of active region 340 in FIG. 3A applies to FIG. 3B unless mentioned otherwise. As shown in FIG. 3B, each STI region 360 can include an insulating layer 368. As discussed below in method 400B with reference to FIG. 4B, insulating layers 368 can be formed by replacing certain portions of fin structure 110 with dielectric materials. Insulating layers 368 can serve a similar purpose as insulating layers 168 in FIGS. 1, 2A-2C, and 3A to facilitate the formation of wrap-around S/D contacts 163. As shown in FIG. 3B, active region 340 can include two wrap-around S/D contacts 163 in contact with the two S/D epitaxial structures 125 and insulating layers 368. The two wrap-around S/D contacts 163 can be any of S/D contacts 163 as discussed above with reference to FIGS. 1 and 2A-2C. In some embodiments, each STI region 360 can include gate structures 365 disposed in insulating layer 368. Each gate structure 365 can include a gate electrode 361, a gate spacer 362, and a gate dielectric 363. In some embodiments, gate structures 365 can be dummy gates with gate electrode 361 being a polysilicon gate formed together with sacrificial gates in active region 340, as described with reference to FIGS. 4B and 7. In some embodiments, gate structures 365 can be metal gates with gate electrode 361 being a metal gate by replacing its polysilicon with metal in the same process of replacing the dummy gates with gate structures in active region 340, as described with reference to FIGS. 4B and 21. In some embodiments, the presence of gate structures 365 in STI region 360 can maintain a uniformity of mechanical properties of semiconductor device 300 during a manufacturing process to avoid dishing issues due to a loading effect.

Although FIGS. 3A and 3B show that semiconductor device 300 can include wrap-around S/D contacts 163 with the geometry as shown in FIG. 2A as examples, it should be understood that some or all of these wrap-around S/D contacts 163 can have the geometries as shown in FIGS. 2B and/or 2C.

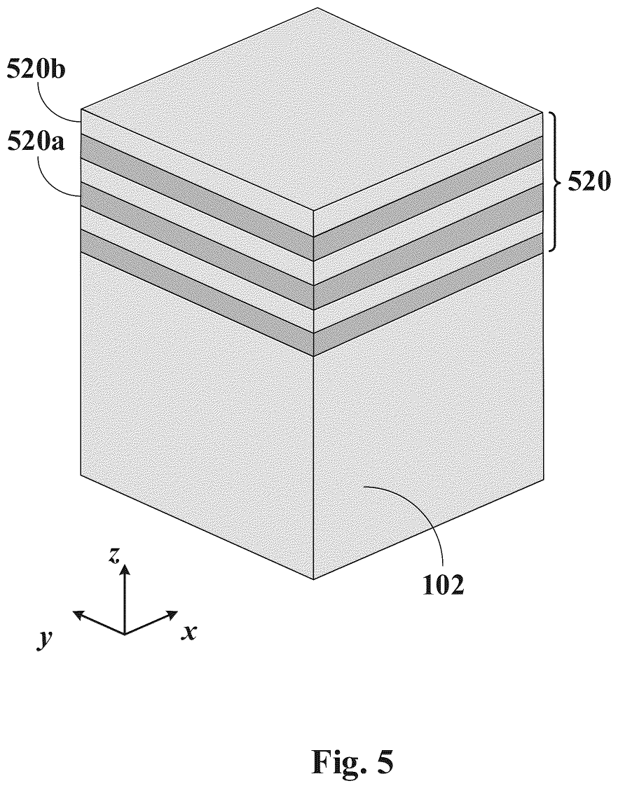

According to some embodiments, FIGS. 4A and 4B illustrate flowcharts of fabrication methods 400A and 400B, respectively, for the formation of semiconductor devices 100 or 300 shown in FIGS. 1-3B. This disclosure is not limited to this operational description and additional operations may be performed. Other fabrication operations can be performed between the various operations of methods 400A and 400B and are omitted merely for clarity. Moreover, not all operations may be needed to perform the disclosure provided herein. Additionally, some of the operations may be performed simultaneously, or in a different order than the ones shown in FIGS. 4A and 4B. In some embodiments, one or more other operations may be performed in addition to or in place of the presently-described operations. For illustrative purposes, methods 400A and 400B are described with reference to the structures shown in FIGS. 5-24. The discussion of elements in FIGS. 1-3C with the same annotations applies to FIGS. 5-24, unless mentioned otherwise.

Referring to FIG. 4A, method 400A begins with an operation 405 and the process of forming a fin structure on a substrate (e.g., substrate 102). In some embodiments, forming the fin structure can include forming a stack of alternating first and second NS layers on the substrate. FIG. 5 is an isometric view of substrate 102 and the formation of a stack 520 of alternating first and second NS layers 520a and 520b. In some embodiments, first and second NS layers 520a and 520b are formed on an exposed top surface of substrate 102. In some embodiments, first NS layers 520a are sacrificial NS layers subject to subsequent removal and second NS layers 520b correspond to NS layers 120 shown in FIGS. 1-3B. In some embodiments, the material of first NS layers 520a in stack 520 is selected so that first NS layers 520a can be selectively removed via etching from stack 520 without removing second NS layers 520b. For example, first NS layers 520a can be SiGe NS layers and second NS layers 520b can be Si NS layers.

First and second NS layers 520a and 520b can be grown with any suitable method. For example, first and second NS layers 520a and 520b can be grown with a chemical vapor deposition (CVD) process with precursor gases, like silane (SiH₄), disilane (Si₂H₆), dichlorosilane (SiH₂Cl₂), trichlorosilane (SiHCl₃), germane (GeH₄), digermane (Ge₂H₆), other suitable gases, or combinations thereof. In some embodiments, first NS layers 520a can include Ge with a concentration between about 20% and about 30%, while second NS layers 120 can be substantially germanium-free—e.g., have a Ge concentration less than about 1%. In some embodiments, second NS layers 520b, which correspond to NS layers 120 in FIG. 1, form the channel region of transistor 105 and can be lightly doped or intrinsic (e.g., un-doped). If lightly doped, the doping level of second NS layers 520b is less than about 10¹³ atoms/cm³. First and second NS layers 520a and 520b can be sequentially deposited without a vacuum break (e.g., in-situ) to avoid the formation of any intervening layers. In some embodiments, first NS layers 520a can be doped to increase their etching selectivity compared to second NS layers 520b in a subsequent etching operation.

In some embodiments, a thickness of first NS layers 520a controls the spacing between every other second NS layer 520b in stack 520. The thickness of first and second NS layers 520a and 520b can range, for example, from about 3 nm to about 15 nm. Since first and second NS layers 520a and 520b are grown individually, the thickness of each NS layer can be adjusted independently based, for example, on the deposition time. In some embodiments, additional or fewer number of first and second NS layers 520a and 520b can be formed in stack 520. In some embodiments, a total number of NS layers can be 2n, where n is the number of first NS layers 520a or the number of second NS layers 520b in stack 520. In some embodiments, n can be 1, 2, 3, 4, 5, 6, or any integer number greater than 6.

Referring to FIG. 4, operation 405 can further include a process of patterning stack 520 to form the fin structure. In some embodiments, stack 520 is patterned to form the fin structure with a width along the y-direction and a length along the x-direction. The fin structure can be formed by patterning with any suitable method. For example, the fin structure may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. In some embodiments, a sacrificial layer is formed over stack 520 and patterned using a photolithography process. Spacers are formed alongside the patterned sacrificial layer using a self-aligned process. The sacrificial layer is then removed, and the remaining spacers may then be used as masking structures to pattern the fin structures.

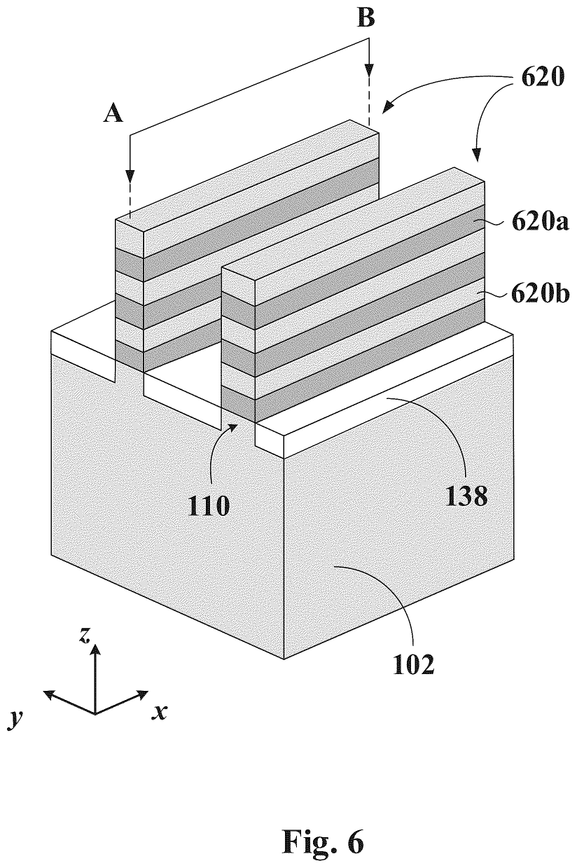

By way of example and not limitation, FIG. 6 is an isometric view of fin structures 620 formed from stack 520 with the aforementioned patterning process. In some embodiments, fin structures 620 can be formed by etching first and second NS layers 520a and 520b into first and second NS layers 620a and 620b. In some embodiments, the aforementioned patterning process does not terminate on the top surface of substrate 102 but continues to etch a top portion substrate 102 to form fin structures 110 from substrate 102 under fin structures 620. Since fin structures 620 and fin structures 110 are formed with the same patterning process, fin structures 620 and fin structures 110 are substantially aligned to each other. For example, sidewall surfaces of fin structures 620 in the x-z plane and y-z plane are substantially aligned to respective sidewall surfaces of fin structures 110 as shown in FIG. 6.

Additional fin structures, like fin structures 620, can be formed on substrate 102 in the same or different area of substrate 102. These additional fin structures are not shown in FIG. 6 for simplicity. By way of example and not limitation, each fin structure 620 has a width along the y-direction between about 15 nm and about 150 nm.

In some embodiments, NS layers 620a and 620b are referred to as “nano-sheets” when their width along the y-direction is substantially different from their height along the z-direction—for example, when their width is larger/narrower than their height. In some embodiments, NS layers 620a and 620b can also be referred to as “nano-wires” when their width along the y-direction is substantially equal to their height along the z-direction. In some embodiments, NS layers 620a and 620b are deposited as nano-sheets and subsequently patterned to form nano-wires with substantially equal height and width. By way of example and not limitation, NS layers 620a and 620b will be described in the context of nano-sheets (NS) layers. Based on the disclosure herein, nano-wires (NW) are within the spirit and the scope of this disclosure. Further, for example purposes and without limiting the scope of this disclosure, first and second NS layers 620a and 620b in method 400 will be described in the context of SiGe and Si NS layers, respectively.

In some embodiments, after the formation of fin structures 620, STI regions 138 can be formed on etched or recessed portions of substrate 102 to cover sidewall surfaces of fin structures 110. In some embodiments, STI regions 138 can electrically isolate fin structures 110 and include one or more silicon oxide based dielectrics. By way of example and not limitation, STI regions 138 can be formed as follows. An isolation structure material (e.g., a silicon oxide based dielectric) is blanket deposited over fin structures 620 and substrate 102. The as-deposited isolation structure material is planarized (e.g., with a chemical mechanical polishing (CMP) process) so that the top surface of the isolation structure material is substantially coplanar with the top surface of fin structures 620. The planarized isolation structure material is subsequently etched back so that the resulting STI regions 138 has a height substantially similar to fin structures 110, as shown in FIG. 6. In some embodiments, fin structures 620 protrudes from STI regions 138 so that STI regions 138 does not cover sidewall portions of fin structures 620 as shown in FIG. 6.

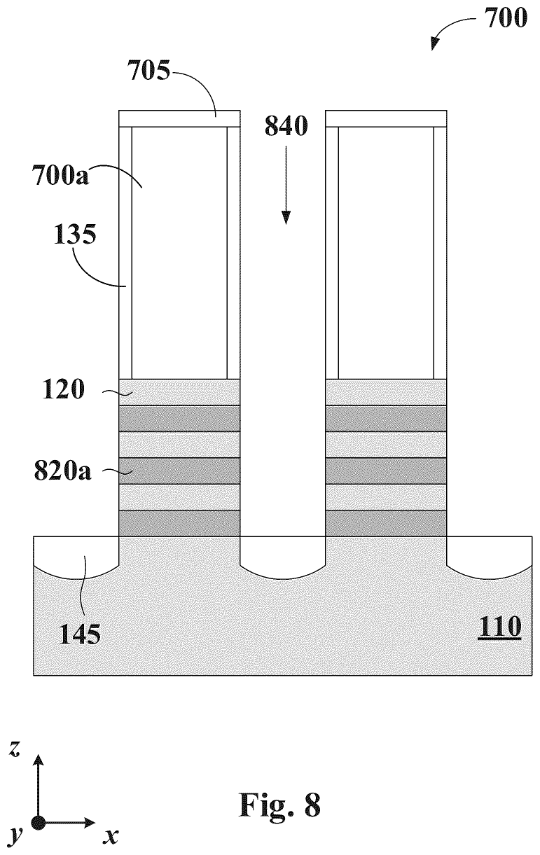

Referring to FIG. 4A, method 400 continues with an operation 410 and the process of forming a source/drain region on the fin structure. Operation 410 can start with removing portions of the fin structures to form openings in the fin structures, including (i) forming sacrificial gate structures 700, as described with reference to FIG. 7 and (ii) removing the portions of fin structure 620 exposed by sacrificial gate structures 700, as described with reference to FIG. 8.

In some embodiments, sacrificial gate structures 700 are formed with their length along the y-direction—e.g., perpendicular to fin structures 620 shown in the isometric view of FIG. 6—and their width along the x-direction. By way of example and not limitation, FIG. 7 is a cross-sectional view of FIG. 6 along cut-line A-B. FIG. 7 shows sacrificial gate structures 700 formed on portions of fin structures 620. Because FIG. 7 is a cross-sectional view, as opposed to an isometric view, portions of sacrificial gate structures 700 covering sidewall portions of fin structures 620 are not shown. Further, in the cross-sectional view of FIG. 7, only one of fin structures 620 from FIG. 6 is shown. In some embodiments, portions of sacrificial gate structures 700 are formed between fin structures 620 and on STI regions 138 shown in FIG. 6.

In some embodiments, sacrificial gate structures 700 can cover top and sidewall portions of fin structures 620. Sacrificial gate structures 700 are subsequently replaced with gate structures 115 shown in FIG. 1 during a subsequent gate replacement process. Sacrificial gate structures 700 can include a sacrificial gate electrode 700a formed on a sacrificial gate dielectric not shown in FIG. 7 for simplicity. Sacrificial gate structures 700 can also include capping layers 705 formed on top surfaces of sacrificial gate structures 700. In some embodiments, capping layers 705 can protect sacrificial gate electrode 700a from subsequent etching operations. At this fabrication stage, gate spacers 135 can be formed on side surfaces of sacrificial gate structures 700. As discussed above, gate spacers 135 are not removed during the gate replacement process; instead, gate spacers 135 facilitate the formation of gate structures 115 as shown in FIGS. 1-2C.

By way of example and not limitation, sacrificial gate structures 700 can be formed by depositing and patterning sacrificial gate electrode 700a over fin structures 620. In some embodiments, sacrificial gate structures 700 are formed over multiple fin structures 620. As shown in FIG. 7, portions of fin structures 620 are not covered by sacrificial gate structures 700. This is because the length of sacrificial gate structures 700 is narrower than the length of fin structures 620 along the x-direction. In some embodiments, sacrificial gate structures 700 are used as masking structures in subsequent etching operations to define the channel region of transistors 105 shown in FIG. 1. For this reason, the lateral dimensions (e.g., the width and length) of sacrificial gate structures 700 and gate structures 115 are substantially similar.

Referring to FIG. 8, portions of fin structures 620 not covered by sacrificial gate structures 700 can be removed. In some embodiments, the removal process involves a dry etching process, a wet etching process, or combinations thereof. The removal process is selective towards first NS layers 620a and second NS layers 620b, shaping them into first NS layers 820a and NS layers 120, respectively. The removal process can further remove portions of fin structure 110. In some embodiments, the dry etching process includes etchants having an oxygen-containing gas, a fluorine-containing gas (e.g., carbon tetrafluoride (CF₄), sulfur hexafluoride (SF₆), difluoromethane (CH₂F₂), trifluoromethane (CHF₃), and/or hexafluoroethane (C₂F₆)); a chlorine-containing gas (e.g., chlorine (Cl₂), chloroform (CHCl₃), carbon tetrachloride (CCl₄), and/or boron trichloride (BCl₃)); a bromine-containing gas (e.g., hydrogen bromide (HBr) and/or bromoform (CHBr₃)); an iodine-containing gas; other suitable etching gases and/or plasmas; or combinations thereof. The wet etching chemistry can include diluted hydrofluoric acid (DHF), potassium hydroxide (KOH) solution, ammonia; a solution containing hydrofluoric acid (HF), nitric acid (HNO₃), acetic acid (CH₃COOH); or combinations thereof.

In some embodiments, the etchants of the aforementioned etching process do not substantially etch sacrificial gate structures 700—which is protected by capping layers 705 and gate spacers 135—and STI regions 138 shown in FIG. 6. This is because capping layers 705, gate spacers 135, and STI regions 138 include materials with a low etching selectivity, such as a silicon nitride based material (e.g., silicon nitride, silicon carbon nitride, and silicon carbon oxy-nitride) or silicon oxide based materials. In some embodiments, STI regions 138 shown in FIG. 6 are used as an etch stop layer for the etching process described above.

After removing the portions of fin structures 620 not covered by sacrificial gate structures 700, openings 840 are formed in each fin structure 620 as shown in FIG. 8. Openings 840 divide each fin structure 620 into separate portions, with each portion covered by a sacrificial gate structure 700. In some embodiments, openings 840 can extend into fin structure 110 by removing portions of fin structure in the aforementioned etching process, and isolation layers 145 can be formed on bottom surfaces of openings 840 by depositing a dielectric material (e.g., a silicon oxide based dielectric) in openings 840.

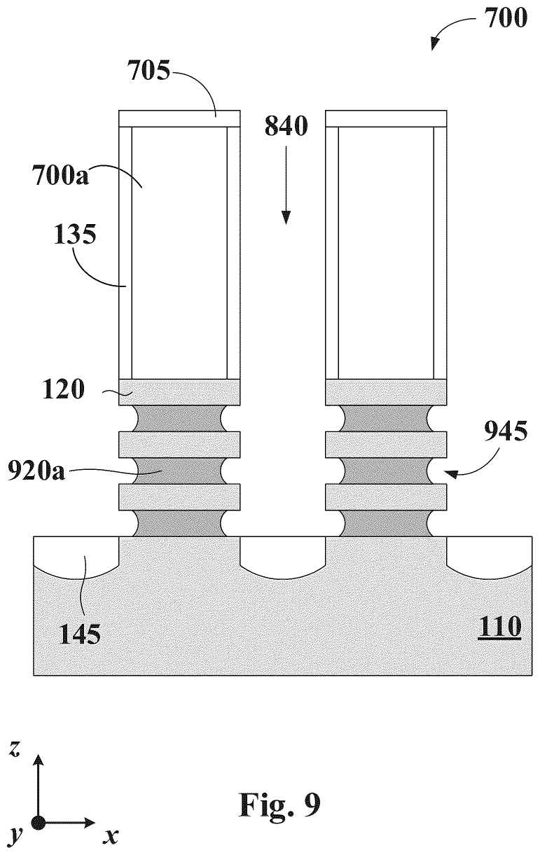

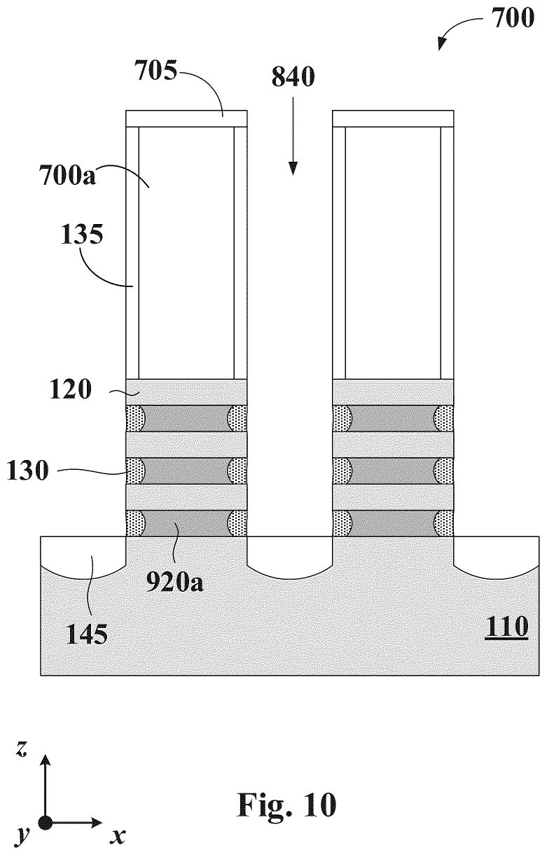

Referring to FIG. 4A, operation 410 can continue with a process of forming inner spacers prior to forming the S/D region. The process of forming inner spacers can include (i) selectively etching edge portions of first NS layers 820a to form recess structures 945, as described with reference to FIG. 9 and (ii) forming inner spacer structures 130 in recess structures 945, as described with reference to FIG. 10. According to some embodiments, FIG. 9 shows the structure of FIG. 8 after exposed edges of first NS layers 820a are laterally etched (e.g., recessed) along the x-direction and turned into first NS layers 920a. According to some embodiments, exposed edges of first NS layers 820a are recessed (e.g., partially etched) by an amount that ranges from about 3 nm to about 10 nm along the x-direction as shown in FIG. 9 to form recesses structures 945.

In some embodiments, the selective etching of first NS layers 820a can be achieved with a dry etching process selective towards SiGe. For example, halogen-based chemistries exhibit a high etching selectivity towards Ge and a low etching selectivity towards Si. Therefore, halogen gases etch Ge-containing layers, such as first NS layers 820a, at a higher etching rate than substantially Ge-free layers like NS layers 120. In some embodiments, the halogen-based chemistries include fluorine-based and/or chlorine-based gasses. Alternatively, a wet etching chemistry with high selectivity towards SiGe can be used. By way of example and not limitation, a wet etching chemistry may include a mixture of sulfuric acid (H₂SO₄) and hydrogen peroxide (H₂O₂) (SPM), or a mixture of ammonia hydroxide with H₂O₂ and water (APM). The aforementioned etching processes are timed so that the desired amount of SiGe is removed.

In some embodiments, first NS layers 820a with a higher Ge atomic concentration have a higher etching rate than NS layers 120 with a lower or zero Ge atomic concentration. Therefore, the etching rate of the aforementioned etching processes can be adjusted by modulating the Ge atomic concentration (e.g., the Ge content) in first NS layers 820a. As discussed above, the Ge content in first NS layers 820a can range between about 20% and about 30%. A SiGe nano-sheet layer with about 20% Ge can be etched slower than a SiGe nano-sheet layer with about 30% Ge. Consequently, the Ge concentration can be adjusted accordingly to achieve the desired etching rate and selectivity between first NS layers 820a and NS layers 120.

Referring to FIGS. 9 and 10, once recessed structures 945 are formed, a dielectric layer can be blanket deposited over the entire structure of FIG. 9, and the portion of the dielectric layer outside recess structures 945 can be removed, leaving inner spacer structures 130 behind filling recessed structures 945, as described with reference to FIG. 10.

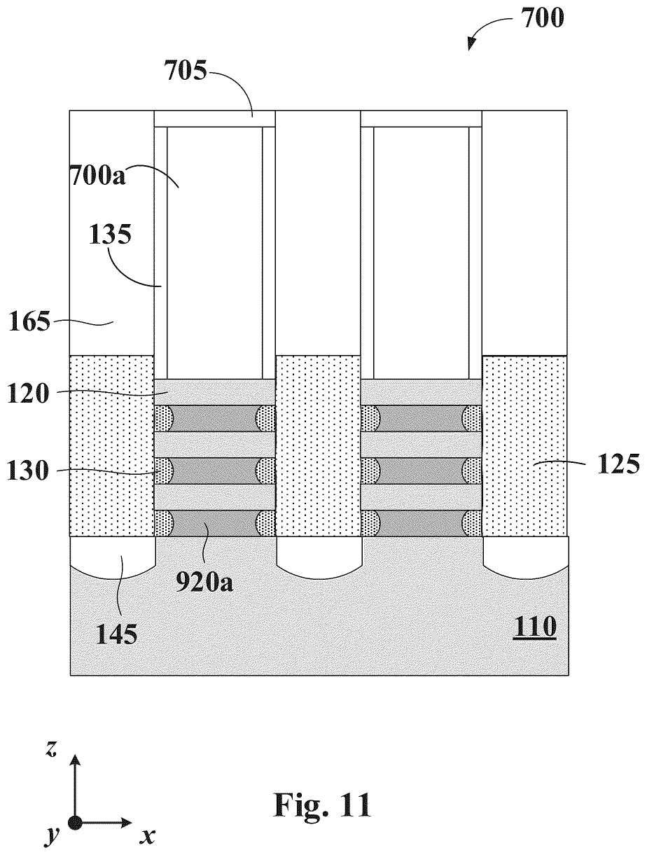

Referring to FIG. 4A, after forming inner spacer structures 130, operation 410 can continue with a process of epitaxially growing the S/D region in opening 840. For example, as described with reference to FIG. 11, S/D epitaxial structures 125 can be formed by epitaxially growing a semiconductor material in openings 840.

In some embodiments, as described with reference to FIG. 11, S/D epitaxial structures 125 can be epitaxially grown with a CVD process similar to the one used in operation 405 to form first and second NS layers 520a and 520b, as described with reference to FIG. 5. In some embodiments, S/D epitaxial structures 125 can be epitaxially grown on side surfaces of second NS layers 120 in a horizontal direction (e.g., along the x-axis) to fill up bottom portions of openings 840. In some embodiments, S/D epitaxial structures 125 can be grown using a plasma-enhanced CVD (PECVD) process. In some embodiments, precursor gases (e.g., SiH₄, SiH₂Cl₂, SiHCl₃, or a combination thereof) can be used to grow a semiconductor material (e.g., Si) having a crystalline structure the same as or similar to the crystalline structure of NS layers 120. In some embodiments, etching gases (e.g., hydrogen chloride (HCl)) can be used to selectively remove the semiconductor material with an amorphous structure formed on dielectric surfaces (e.g., side surfaces of inner spacer structures 130 and gate spacers 135). Removing the semiconductor material with the amorphous structure can ensure that the crystal structure of S/D epitaxial structures 125 is crystalline. In some embodiments, dopant precursor gases, such as phosphanes (PH₃), arsanes (AsH₃), stibane (SbH₃), or a combination thereof, can be used in the CVD process or the PECVD process to dope S/D epitaxial structures 125. In some embodiments, after growing S/D epitaxial structures 125, ILD layers 165 can be formed on S/D epitaxial structures 125 and in openings 840 by depositing a dielectric material (e.g., a silicon oxide based dielectric) in openings 840.

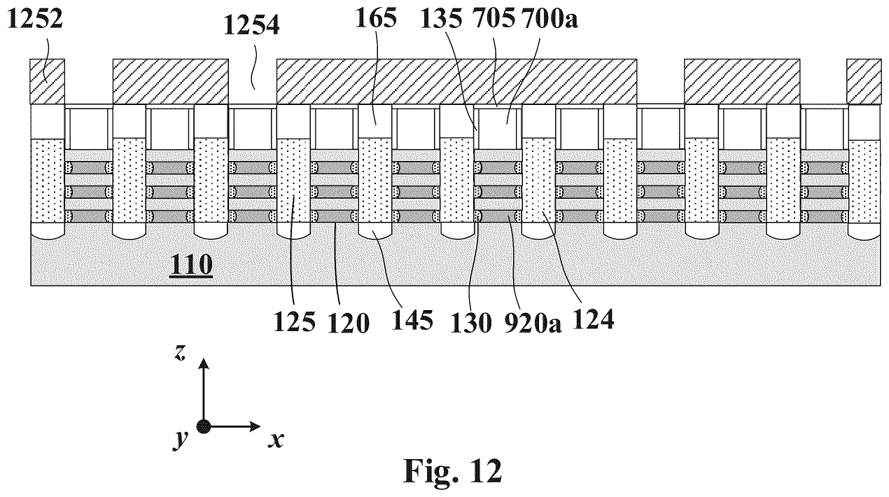

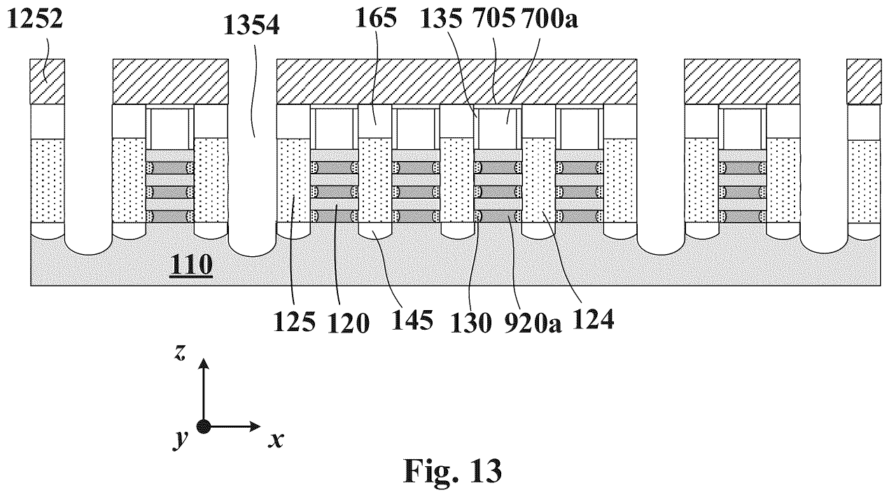

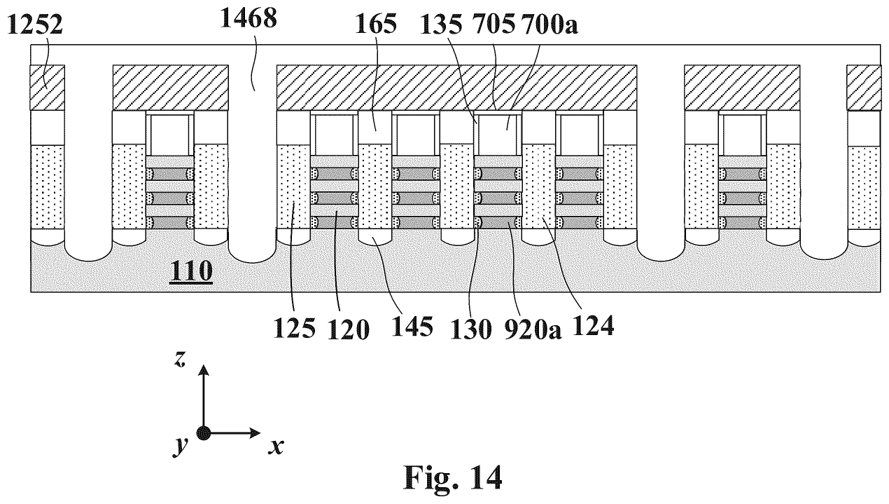

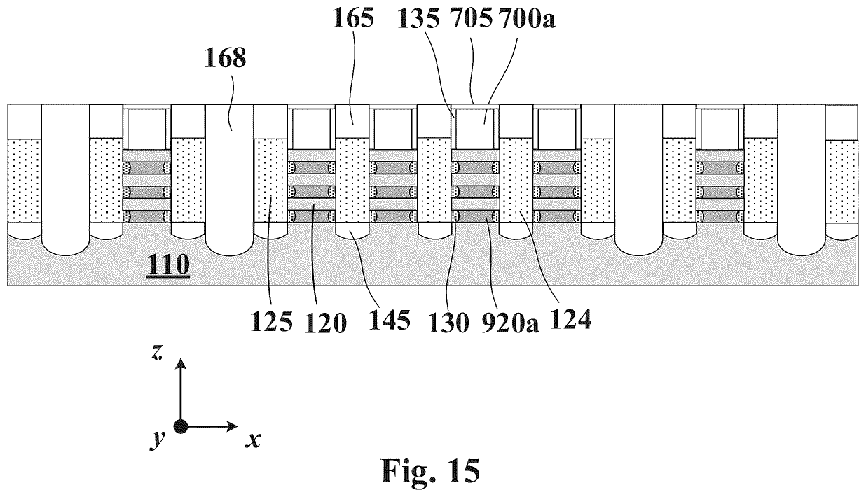

Referring to FIG. 4A, method 400 continues with an operation 415, in which an insulating layer is formed adjacent to the S/D region, as described with reference to FIGS. 12-15. Referring to FIG. 12, multiple structures in FIG. 11 can be formed together based on the same fin structure 110 and aligned in a series. A mask 1252 can be formed over ILD layers 165 and capping layers 705. Mask 1252 can include windows 1254 exposing certain capping layers 705. Windows 1254 define regions in which the insulating layers are formed. As described with reference to FIG. 13, capping layers 705 exposed by windows 1254 can be removed. Furthermore, materials under these capping layers 705, such as sacrificial gate electrode 700a, gate spacers 135, first NS layers 920a, NS layers 120, inner spacer structures 130, and portions of fin structure 110 in windows 1254 can also be removed to form openings 1354. In some embodiments, the removal process involves a dry etching process, a wet etching process, or combinations thereof. After the formation of openings 1354, an insulating layer 1468 (e.g., a silicon oxide, low-k silicon nitride, or silicon) can blanket deposited over mask 1252 and in openings 1354, as described with reference to FIG. 14. Portions of insulating layer 1468 above ILD layers 165 and capping layers 705 and mask 1252 can subsequently be removed by a polishing process (e.g., with a chemical mechanical polishing (CMP) process), leaving insulating layers 168 adjacent to S/D epitaxial structures 125, as described with reference to FIG. 15.

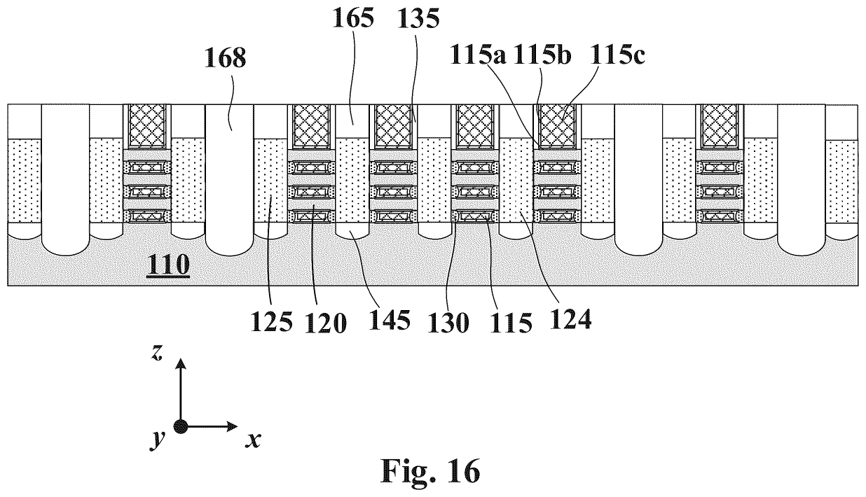

Referring to FIG. 4A, method 400A can continue with an operation 420 and a process of forming a gate structure. The process of forming metal gate structures can include (i) removing sacrificial gate structures 700 and first NS layers 920a and (ii) forming metal gate structures 115 to surround second NS layers 120, as described with reference to FIG. 16.

In some embodiments, removing sacrificial gate structures 700 can include removing capping layer 705 to expose sacrificial gate electrode 700a, and subsequently, removing sacrificial gate electrode 700a to expose fin structures 620 between S/D epitaxial structures 125. In some embodiments, removing first NS layers 920a can include selectively etching first NS layers 920a without removing NS layers 120.

In some embodiments, forming metal gate structures 115 can include (i) forming interfacial dielectric layer 115a on exposed surfaces of second NS layers 120, (ii) forming gate dielectric layer 115b on interfacial dielectric layer 115a, and (iii) forming gate electrode 115c on gate dielectric layer 115b, as described with reference to FIG. 16. As discussed above, metal gate structures 115 are electrically isolated from S/D epitaxial structures 125 by inner spacer structures 130 and gate spacers 135.

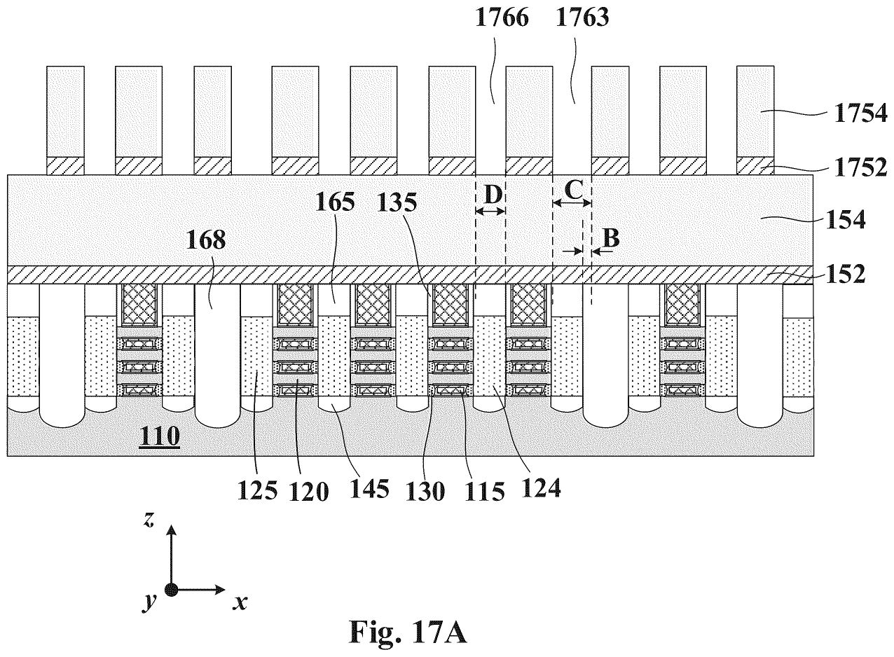

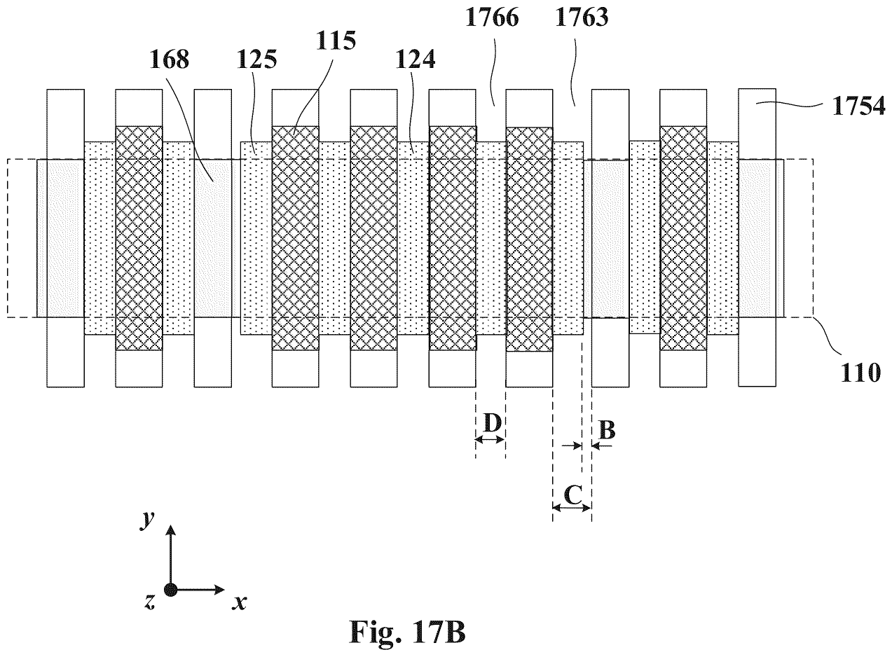

Referring to FIG. 4A, method 400A can continue with an operation 425 and a process of forming an etch stop layer, a dielectric layer and a patterned mask, as described with reference to FIGS. 17A and 17B. FIG. 17A illustrates a cross-sectional (e.g., along the x-z plane) view of an intermediate stage of forming semiconductor device 300. Correspondingly, FIG. 17B illustrates a top view (e.g., along the z-axis) of the intermediate stage of forming semiconductor device 300. Referring to FIG. 17A, ESL 152 can be formed over gate structures 115, ILD layers 165, and insulating layers 168. Dielectric layer 154 can then be formed over ESL 152. In some embodiments, ESL 152 and dielectric layer 154 can be formed by a sequential deposition of dielectric layers, such as silicon oxide and silicon nitride. Referring to FIG. 17A, in some embodiments, mask layers 1752 and 1754 can be formed on dielectric layer 154. Mask layers 1752 and 1754 can include windows 1766 and 1763, which define regions for a subsequent etching process to form contact openings. For illustration purpose, mask layer 1752, dielectric layer 154, and ESL 152 are not shown in FIG. 17B. In some embodiments, windows 1766 can be directly above S/D epitaxial structures 124, with a width corresponding to width D of S/D contact 166 as shown in FIG. 2A. Similarly, windows 1763 can be directly above S/D epitaxial structures 125 and insulating layer 168, with a width corresponding to width C of S/D contact 163 as shown in FIG. 2A. In particular, the vertical overlap between each window 1763 and its corresponding insulating layer 168 can be the same as horizontal distance B as shown in FIG. 2A.

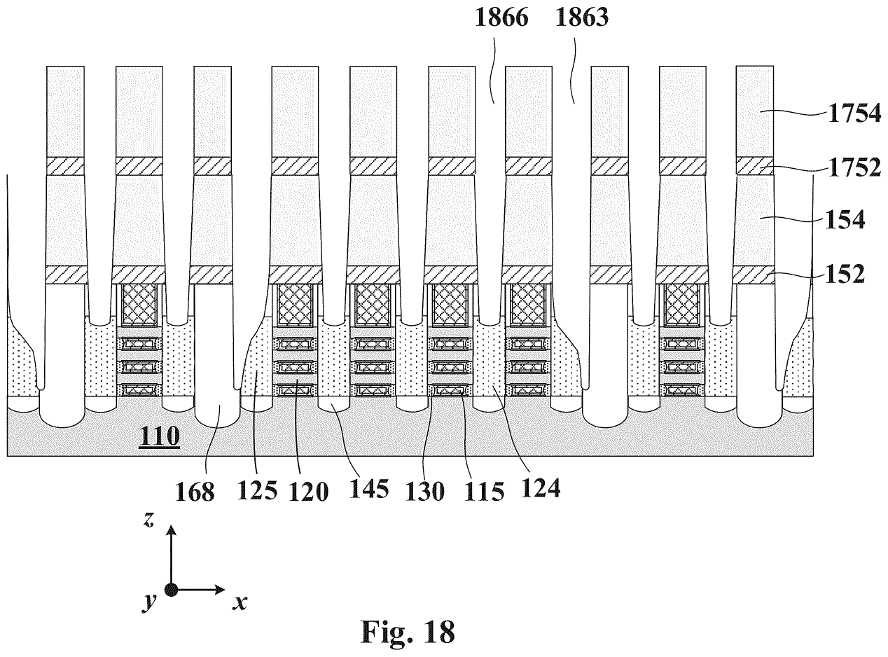

Referring to FIG. 4A, method 400A can continue with operation 430 and a process of forming a contact opening. For example, as described with reference to FIG. 18, contact openings 1866 and 1863 can be formed according to windows 1766 and 1763 as shown in FIG. 17, respectively. In some embodiments, contact openings 1866 and 1863 can be formed by an etching process involving a dry etching process, a wet etching process, or combinations thereof. The etching process can sequentially remove portions of dielectric layer 154, ESL 152, and ILD layers 165 exposed by windows 1766 and 1763. The etching process can further remove portions of S/D epitaxial structures 124 and 125 and insulating layers 168 according to windows 1766 and 1763. In some embodiments, the etching process can be performed by using etchants that etches S/D epitaxial structures 125 and insulating layers 168 at different etching rates. For example, the ratio of the first etching rate on insulating layers 168 to the second etching rate on S/D epitaxial structures 125 can be between about 1 and about 10. By varying such etching selectivity, the etching process can form contact openings 1863 with a geometry corresponding to S/D contacts in FIGS. 2A-2C. In some embodiments, because the width of windows 1763 is greater than the width of windows 1766, and because insulating layer 168 are removed at a higher rate than S/D epitaxial structures 125, S/D epitaxial structures 125 can have larger surface areas exposed to the etchants compared with S/D epitaxial structures 124 and can be etched faster and deeper than S/D epitaxial structures 124. After contact openings 1866 and 1863 are formed, mask layers 1752 and 1754 can be removed.

Although method 400A shows the embodiment that contact openings 1866 and 1863 are formed simultaneously, in some embodiments, contact openings 1866 and 1863 can be formed separately, for example, by using two different masks, each with windows 1766 or 1763 only, and etch openings 1866 and 1863 one after another.

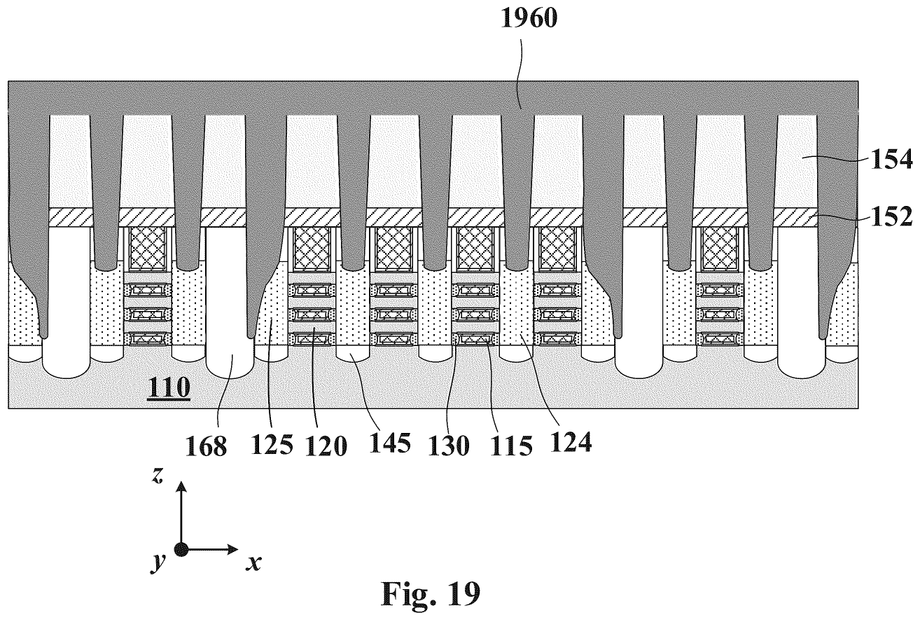

Referring to FIG. 4A, method 400A can continue with operation 435 and a process of forming a source/drain contact structure in the contact opening. For example, as described with reference to FIG. 19, a conductive layer 1960 can be formed by depositing a metallic material (e.g., W, Cu, and/or Mo) in contact openings 1863 and 1866 and on dielectric layer 154. In some embodiments, after depositing the metallic material, a planarization process (such as a CMP process) can be performed to remove excessive metallic material above dielectric layer 154, so that S/D contacts 163 and 166 can be formed as shown in FIG. 3A.

For the formation of semiconductor device 300B as shown in FIG. 3B, method 400B as shown in FIG. 4B can begin with operation 405 and the process of forming fin structures on a substrate (e.g., substrate 102), followed by operation 410 and the process of forming S/D region on the fin structure. Operations 405 and 410 of method 400B are the same as they are in method 400A as described with reference to FIGS. 5-11.

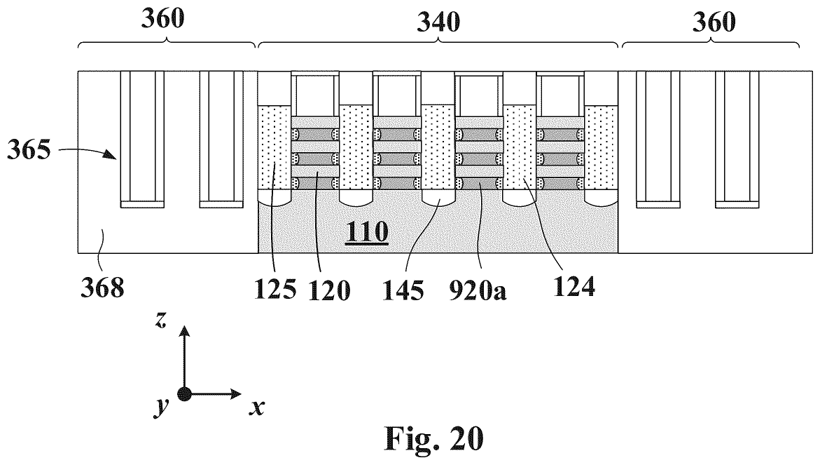

Referring to FIG. 4B, method 400B can continue with operation 445 and a process of forming a shallow trench isolation (STI) region adjacent to the source/drain region. For example, multiple structures in FIG. 11 can be formed together based on the same fin structure 110 and aligned in a series, and then some portions in the series and adjacent to S/D epitaxial structures 125 can be replaced by STI regions 360, as described with reference to FIG. 20. The formation of STI regions 360 can include removing the portions in the series to form openings, forming insulating layers 368 in the openings, and forming gate structures 365 in insulating layers 368. Forming insulating layers 368 can include blanket depositing a dielectric material (e.g., a silicon oxide, low-k silicon nitride, or silicon) in the openings. Forming gate structures 365 can include forming gate spacers, sacrificial gate electrode, and capping layers similar to the process of forming sacrificial gate structures 700 as described with reference to FIG. 7 and is not repeated for simplicity. Although FIG. 20 shows that active region 340 formed between two STI regions 360 includes four sets of NS layers 120 separated by S/D epitaxial structures 124, it should be understood that any number of sets of NS layers 120 can be formed between two STI regions 360.

Referring to FIG. 4B, method 400B can continue with operation 420 and the process of forming a gate structure, as described with reference to FIG. 21. Operation 420 of method 400B is the same as that in method 400A as described with reference to FIG. 16 and is not repeated for simplicity. In some embodiments, in operation 420 of method 400B, the sacrificial gate electrode of gate structures 365 can also be replaced with a gate dielectric and a gate electrode as in gate structure 115.

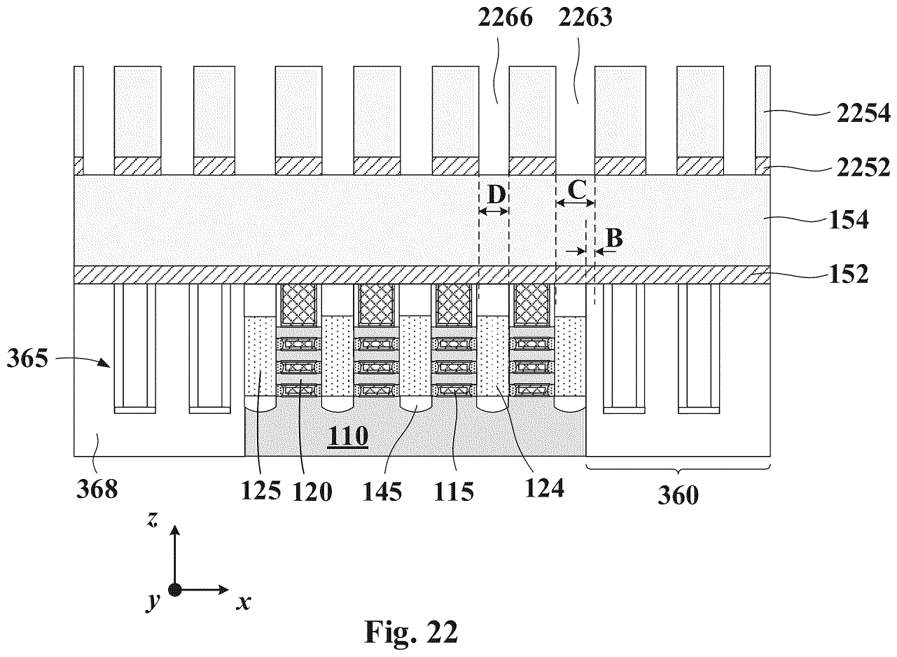

Referring to FIG. 4B, method 400B can continue with an operation 455 and a process of forming an etch stop layer, a dielectric layer, and a patterned mask. Operation 455 of method 400B is similar to operation 425 of method 400A as described with reference to FIGS. 17A and 17B. For example, in operation 455 as described with reference to FIG. 22, ESL 152 can be formed over gate structures 115, ILD layers 165, and STI regions 360. Dielectric layer 154 can then be formed over ESL 152 and mask layers 2252 and 2254 and then be formed on dielectric layer 154. Mask layers 2252 and 2254 can include windows 2266 and 2263, which define regions for a subsequent etching process to form contact openings. For example, windows 2266 can be directly above S/D epitaxial structures 124, with a width corresponding to width D of S/D contact 166 as shown in FIG. 2A. Similarly, windows 2263 can be directly above S/D epitaxial structures 125 and insulating layers 368, with a width corresponding to width C of S/D contact 163 as shown in FIG. 2A. In particular, the vertical overlap between each window 2263 and its corresponding insulating layers 368 can be the same as horizontal distance B as shown in FIG. 2A.

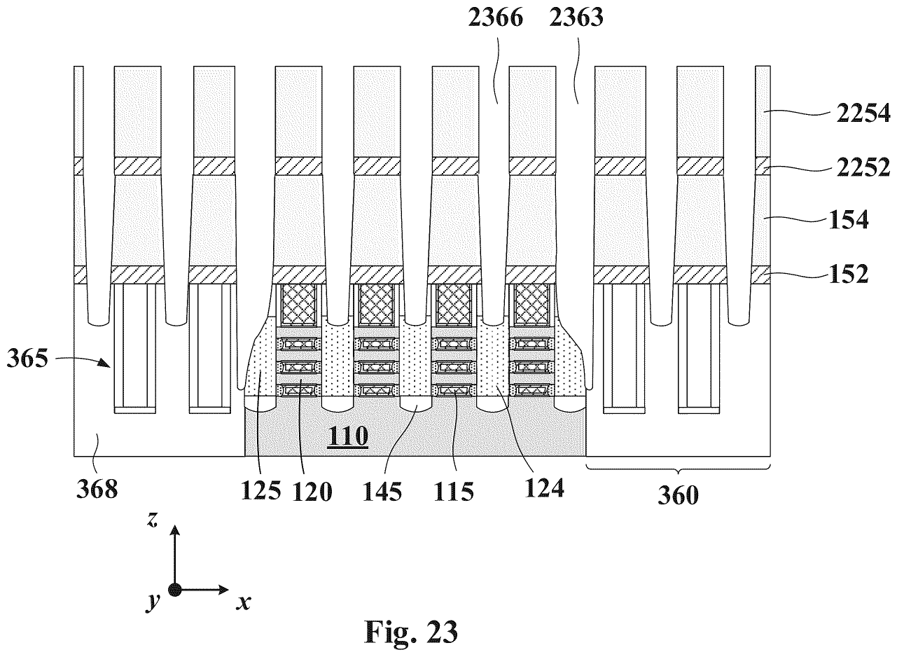

Referring to FIG. 4B, method 400B can continue with an operation 460 and a process of forming a contact opening into the source/drain region and the STI region, according to the patterned mask. Operation 460 of method 400B is similar to operation 430 of method 400A as described with reference to FIG. 18. For example, in operation 460 as described with reference to FIG. 23, contact openings 2366 and 2363 can be formed according to windows 2266 and 2263 as shown in FIG. 22, respectively. Contact openings 2366 and 2363 can be formed by an etching process the same as that in operation 430 of method 400A, which is not repeated for simplicity. After operation 460, contact openings 2363 exposing S/D epitaxial structures 125 and insulating layers 368 can have a geometry corresponding to S/D contacts in FIGS. 2A-2C, depending on the etching selectivity of the etchant used in the etching process, as discussed in operation 430 of method 400A. After contact openings 2366 and 2363 are formed, mask layers 2252 and 2254 can be removed.

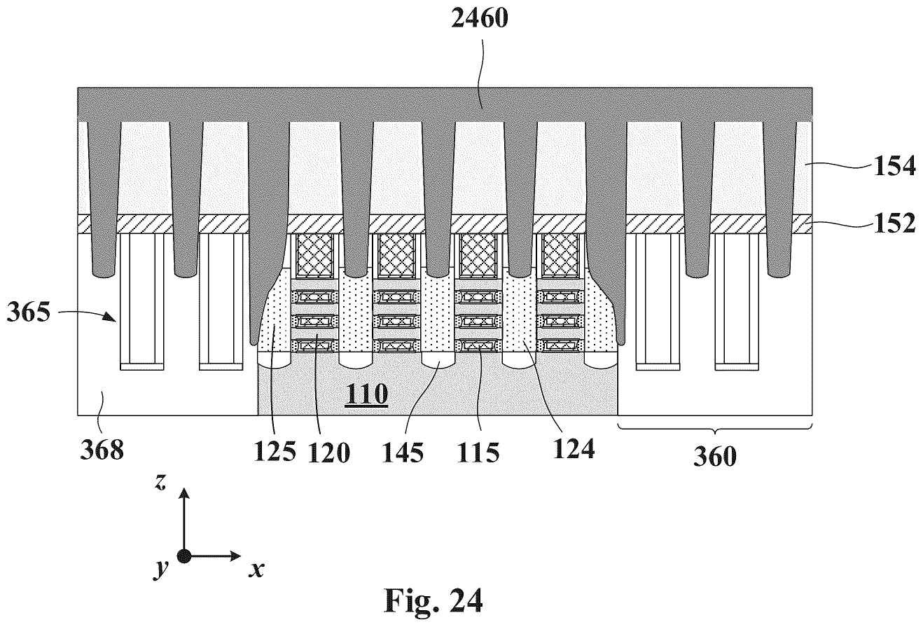

Referring to FIG. 4B, method 400B can continue with operation 435 and the process of forming a source/drain contact structure in the contact opening. Operation 435 of method 400B is the same as that in method 400A as described with reference to FIG. 19. For example, as described with reference to FIG. 24, a conductive layer 2460 can be formed by depositing a metallic material (e.g., W, Cu, and/or Mo) in contact openings 2363 and 2366 and on dielectric layer 154. In some embodiments, after depositing the metallic material, a planarization process (such as a CMP process) can be performed to remove excessive metallic material above dielectric layer 154, and leaving S/D contacts 163 and 166 as shown in FIG. 3B.

The embodiments described herein are directed to a structure of a semiconductor device and a method of forming the structure. The structure can include a GAAFET with multiple channel layers on a substrate. The GAAFET can include an S/D region adjacent to the channel layers. The structure can further include an insulating layer adjacent to an S/D region and an S/D contact structure protruding into the insulating layer and the S/D structure. The S/D contact structure can wrap around a majority of a side surface of the S/D region, and can vertically extend between the insulating layer and the S/D region to or below a horizontal level of a bottom most channel layer of the GAAFET. The method of forming the structure can include forming the S/D region adjacent to the channel layers and forming the insulating layer adjacent to the S/D region. The method can further include forming a dielectric layer and a patterned mask on the insulating layer and the S/D region. The patterned mask can have a window overlapping with an interface between the insulating layer and the S/D region. The method can further include forming an opening according to the patterned mask through the dielectric layer and protruding into the insulating layer and the S/D region. The opening can be formed by etching the insulating layer and the S/D region with different selectivity such that the opening extends deeper in the insulating layer than in the S/D region. The method can further include depositing a conductive material in the opening to form the S/D contact structure wrapping around the S/D region.

In some embodiments, a structure includes a fin structure on a substrate. The fin structure includes a plurality of channel layers. The structure further includes a gate structure surrounding each of the plurality of channel layers, a source/drain (S/D) region adjacent to the fin structure and in contact with the plurality of channel layers, an insulating layer adjacent to the S/D region, and a dielectric layer on the S/D region and the insulating layer. The structure further includes an S/D contact structure through the dielectric layer and in contact with the S/D region and the insulating layer. A bottom surface of the S/D contact structure is below a top surface of a bottommost channel layer of the plurality of channel layers.

In some embodiments, a structure includes a first channel layer on a horizontal surface of a substrate and a second channel layer on the first channel layer. The structure further includes a gate structure surrounding the first and second channel layers, a source/drain (S/D) region in contact with the first and second channel layers and an insulating layer adjacent to the S/D region. The structure further includes an S/D contact structure in contact with the S/D region and the insulating layer. A first horizontal distance between the first channel layer and the S/D contact structure is substantially the same as a second horizontal distance between the second channel layer and the S/D contact structure.

In some embodiments, a method includes forming a plurality of channel layers and a plurality of sacrificial layers alternatingly on a substrate. The method further includes forming a fin structure by patterning the plurality of channel layers and the plurality of sacrificial layers. The method further includes forming a source/drain (S/D) region adjacent to the fin structure. The method further includes forming an insulating layer adjacent to the S/D region, replacing the plurality of sacrificial layers by a gate structure surrounding each of the plurality of channel layers, and depositing a dielectric layer on the insulating layer and the S/D region. The method further includes forming an opening through the dielectric layer and protruding into the insulating layer and the S/D region. A bottom surface of the opening is formed to be below a top surface of a bottommost channel layer of the plurality of channel layers. The method further includes depositing a conductive material in the opening to form an S/D contact structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a fin structure on a substrate, wherein the fin structure comprises a plurality of channel layers;
a gate structure surrounding each of the plurality of channel layers;
a source/drain (S/D) region adjacent to the fin structure and in contact with the plurality of channel layers;
an insulating layer adjacent to the S/D region;
a dielectric layer on the S/D region and the insulating layer; and
an S/D contact structure through the dielectric layer and in contact with the S/D region and the insulating layer, wherein a bottom surface of the S/D contact structure is below a top surface of a bottommost channel layer of the plurality of channel layers.

2. The structure of claim 1, wherein an interface between the S/D contact structure and the S/D region comprises a first portion and a second portion above the first portion, wherein a first inclination degree of the first portion is greater than a second inclination degree of the second portion.

3. The structure of claim 1, wherein a first horizontal distance between the S/D contact structure and the bottommost channel layer is greater than a second horizontal distance between the S/D contact structure and a topmost channel layer of the plurality of channel layers.

4. The structure of claim 1, wherein a first horizontal distance between the S/D contact structure and the bottommost channel layer is substantially the same as a second horizontal distance between the S/D contact structure and a second bottommost channel layer of the plurality of channel layers.

5. The structure of claim 1, wherein a vertical distance between the S/D contact structure and the substrate is between about 0 nm and about 50 nm.

6. The structure of claim 1, wherein the S/D contact structure vertically protrudes into the substrate.

7. The structure of claim 1, wherein the S/D contact structure horizontally protrudes into the insulating layer by a width between about 0 nm and about 50 nm.

8. A structure, comprising:
a first channel layer on a horizontal surface of a substrate;
a second channel layer on the first channel layer;
a gate structure surrounding the first and second channel layers;
a source/drain (S/D) region in contact with the first and second channel layers;
an insulating layer adjacent to the S/D region; and
an S/D contact structure in contact with the S/D region and the insulating layer, wherein a first horizontal distance between the first channel layer and the S/D contact structure is substantially the same as a second horizontal distance between the second channel layer and the S/D contact structure.

9. The structure of claim 8, further comprising a third channel layer on the second channel layer and surrounded by the gate structure, wherein a third horizontal distance between the third channel layer and the S/D contact structure is less than the second horizontal distance between the second channel layer and the S/D contact structure.

10. The structure of claim 8, further comprising a dielectric layer on the S/D region and the insulating layer, wherein the S/D contact structure is disposed through the dielectric layer.

11. The structure of claim 8, further comprising an other S/D region in contact with the first and second channel layers and opposing the S/D region.

12. The structure of claim 11, further comprising an other S/D contact structure in contact with the other S/D region, wherein a first vertical height of the S/D contact structure is greater than a second vertical height of the other S/D contact structure.

13. The structure of claim 11, further comprising an other S/D contact structure in contact with the other S/D region, wherein the S/D contact structure and the other S/D contact structure are symmetrical with respect to a vertical plane bisecting the gate structure.

14. A method, comprising:
forming a plurality of channel layers and a plurality of sacrificial layers alternatingly on a substrate;
patterning the plurality of channel layers and the plurality of sacrificial layers to form a fin structure;
forming a source/drain (S/D) region adjacent to the fin structure;
forming an insulating layer adjacent to the S/D region;
replacing the plurality of sacrificial layers by a gate structure surrounding each of the plurality of channel layers;
depositing a dielectric layer on the insulating layer and the S/D region;
forming an opening through the dielectric layer and protruding into the insulating layer and the S/D region, wherein a bottom surface of the opening is below a top surface of a bottommost channel layer of the plurality of channel layers; and
depositing a conductive material in the opening to form an S/D contact structure.

15. The method of claim 14, wherein forming the opening comprises forming a patterned mask on the dielectric layer, and wherein the patterned mask exposes a portion of the dielectric layer directly above an interface between the insulating layer and the S/D region.

16. The method of claim 14, wherein forming the opening comprises forming first and second slanted surfaces on the S/D region and having different inclination degrees.

17. The method of claim 14, wherein forming the opening comprises etching the insulating layer at a first etching rate and etching the S/D region at a second etching rate.

18. The method of claim 17, wherein the first etching rate is greater than the second etching rate.

19. The method of claim 14, wherein forming the insulating layer comprises forming a trench in the substrate and adjacent to the S/D region.

20. The method of claim 19, wherein forming the insulating layer further comprises depositing silicon oxide in the trench.
